(19) United States
(12) Patent Application Publication
(10) Pub. No.: US 2026/0354238 A1
(43) Pub. Date: Nov. 5, 2026

(54) SEMICONDUCTOR PACKAGE SUBSTRATE AND SEMICONDUCTOR PACKAGE INCLUDING SAME

(71) Applicant: LG INNOTEK CO., LTD., Seoul (KR)

(72) Inventors: Jin Soo Bae, Seoul (KR); Yong Seok NA, Seoul (KR); Heon JEONG, Seoul (KR); Soon Gyu KWON, Seoul (KR); Se Ho MYEONG, Seoul (KR); Jung Ho HWANG, Seoul (KR)

(73) Assignee: LG INNOTEK CO., LTD., Seoul (KR)

(21) Appl. No.: 19/102,831

(22) PCT Filed: Aug. 10, 2023
(86) PCT No.: PCT/KR2023/011868

§ 371 Date: Feb. 10, 2025

(30) Foreign Application Priority Data
Aug. 10, 2022 (KR) 10-2022-0099599

(51) Int. Cl. H10W 70/685; H10W 70/63; H10W 90/10

(52) U.S. Cl. CPC H10W 70/687; H10W 70/635; H10W 90/10

(57) ABSTRACT

A semiconductor package substrate according to an embodiment an insulating layer having an upper surface and a lower surface; and a through electrode passing through the upper surface and the lower surface of the insulating layer, wherein a side surface of the through electrode includes a concave portion and a convex portion alternately provided along a vertical direction.

In addition, a semiconductor package substrate according to another embodiment includes an insulating layer having an upper surface and a lower surface; and a through hole passing through the upper surface and the lower surface of the insulating layer, wherein a side wall of the through hole includes a concave portion and a convex portion alternately provided along a vertical direction.

### TECHNICAL FIELD

An embodiment relates to a semiconductor package substrate and a semiconductor package including the same,

### BACKGROUND ART

As performances of electric/electronic products progresses, technologies for disposing a greater number of packages on a circuit board of a limited size are being proposed and studied.

A typical semiconductor package has a structure in which multiple chips are disposed. In addition, recently, products to which the semiconductor package is applied are becoming more high-spec, and multiple chips such as HBM (High Bandwidth Memory) are being adopted, and as a result, a size of the semiconductor package is increasing. As the size of the semiconductor package increases, various components such as including an interposer to connect a plurality of chips are being studied to secure reliability.

In addition, semiconductor packages applied to products providing the Internet of Things (IoT), autonomous vehicles, and high-performance servers require high performance and high reliability in accordance with a trend of high integration. Here, high performance may include conditions such as high-speed transmission of signals, integration of semiconductor packages, and high allowable current of transmittable signals.

At this time, a size of a pad is decreasing in the semiconductor package for miniaturization and integration. The pad may be a mounting pad connected to a chip, or a bump pad connected to various substrates. Here, the various substrates may include additional packages such as a memory substrate, an interposer connecting between the chip and the semiconductor package substrate, and a main board of an electronic device to which the semiconductor package is applied.

Such a semiconductor package substrate is provided as a multilayer semiconductor package substrate. The multilayer semiconductor package substrate includes a through electrode disposed in a through hole formed in a core substrate such as a copper-clad laminate (CCL). At this time, as a wiring of the semiconductor package substrate becomes more complex, a number of layers is increasing. In addition, as an area increases, a thickness of the core substrate is increasing in order to improve strength and warpage characteristics. For example, a thickness of a conventional core substrate is about 200 μm, but recently, the thickness has been increasing several times or more.

At this time, if the thickness of the core substrate increases, it may be difficult to form a through hole in the core substrate using a laser. Therefore, conventionally, a drill machine is used to form a through hole in the core substrate.

However, if a drill machine is used to form a through hole, there is a problem that a manufacturing process time of the semiconductor package substrate increases, and thus productivity or yield decreases. Furthermore, the drill machine is expensive compared to a laser equipment, and thus there is a problem that a manufacturing cost of the semiconductor package substrate increases Accordingly, there is a need for a new method capable of efficiently forming a through hole on a semiconductor package substrate including a core substrate of 200 μm or more.
(Patent Document 1) KR 10-2011-0016266 A

### DISCLOSURE

### Technical Problem

The embodiment provides a semiconductor package substrate having a novel structure and a semiconductor package including the same.

In addition, the embodiment provides a semiconductor package substrate capable of forming a through hole in a core substrate having a size of 200 μm or more using a laser process and a semiconductor package including the same.

In addition, the embodiment provides a semiconductor package substrate capable of reducing a difference between a maximum width and a minimum width in a vertical direction of a through hole and a semiconductor package including the same.

In addition, the embodiment provides a semiconductor package substrate having a slope of an inner wall of the through hole close to a right angle while preventing an expansion of a size of the through hole and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A semiconductor package substrate according to an embodiment comprises an insulating layer having an upper surface and a lower surface; and a through electrode passing through the upper surface and the lower surface of the insulating layer, wherein a side surface of the through electrode includes a concave portion and a convex portion alternately provided along a vertical direction.

In addition, a semiconductor package substrate according to another embodiment comprises an insulating layer having an upper surface and a lower surface; and a through hole passing through the upper surface and the lower surface of the insulating layer, wherein a side wall of the through hole includes a concave portion and a convex portion alternately provided along a vertical direction.

In addition, the semiconductor package substrate further comprises a through electrode disposed in the through hole, wherein a side surface of the through electrode includes a concave portion corresponding to the concave portion of the side wall of the through hole and a convex portion corresponding to the convex portion of the side wall of the through hole.

In addition, the semiconductor package substrate further comprises an insulating member passing through the insulating layer, and the through electrode is provided to surround an outer side of the insulating member.

In addition, the concave portion and the convex portion of the through electrode are provided in multiple numbers alternately along the vertical direction.

In addition, insulating member includes a first portion having a first width in a horizontal direction, and a second portion having a second width different from the first width in the horizontal direction.

In addition, the first width is greater than the second width, the first portion overlaps the concave portion of the through electrode in a horizontal direction, and the second portion overlaps the convex portion of the through electrode in the horizontal direction.

In addition, the insulating layer includes a resin and reinforcing fibers disposed within the resin, and the reinforcing fibers includes a first fiber disposed in a first horizontal direction and a second fiber disposed in a second horizontal direction perpendicular to the first horizontal direction.

In addition, the reinforcing fibers includes a plurality of groups spaced apart from each other along the vertical direction and each having the first and second fibers.

In addition, the concave portion of the through electrode overlaps the reinforcing fibers in the horizontal direction.

In addition, a thickness of the insulating layer in the vertical direction satisfies a range of 250 μm to 1200 μm.

In addition, an inner wall of the through hole of the insulating layer includes a plurality of first inner walls having a protrusion and a second inner wall not having the protrusion.

In addition, the second inner wall means a portion having a concave portion of the inner wall of the through hole.

In addition, the through electrode includes a first portion in contact with the first inner wall and a second portion in contact with the second inner wall. At this time, the first and second through patterns have a step.

In addition, the first portion of the through electrode has a concave portion corresponding to the concave portion of the through hole, and the second portion of the through electrode has a convex portion corresponding to the convex portion of the through hole.

In addition, a thickness of each of the first and second portions of the through electrode in the horizontal direction satisfies a range of 10 μm to 25 μm.

In addition, the thickness of the first portion of the through electrode in the horizontal direction is same as the thickness of the second portion in the horizontal direction.

In addition, the first through electrode includes a first metal layer disposed on the inner wall of the first through hole of the insulating layer, and a second metal layer disposed on the first metal layer.

In addition, a minimum width of a region having a smallest width in an entire region in the vertical direction of the first through hole satisfies a range of 55% to 95% of a maximum width of a region having a greatest width in the entire region in the vertical direction of the first through hole

### Advantageous Effects

The semiconductor package substrate of the embodiment can form a through hole with a minimum difference between a maximum width and a minimum width using laser processing equipment in a first insulating layer having a thickness of 250 μm or more. Accordingly, the embodiment can improve physical characteristics and electrical characteristics of a first through electrode provided in the semiconductor package substrate.

Specifically, the first insulating layer is a core layer including reinforcing fibers.

At this time, in a comparative example, when a through hole is formed in the first insulating layer using laser equipment, the through hole includes regions with different widths along the vertical direction, and a minimum width is less than 50% of a maximum width. Accordingly, the comparative example had a problem in that a non-uniform through electrode is disposed according to a difference in plating speed for each region in a plating process of arranging a through electrode in the through hole.

In addition, the comparative example increase a laser intensity under laser processing conditions in order to minimize the difference between the minimum width and the maximum width. However, in this case, a size expansion problem occurs in which a size of the through hole is formed greater than a target size.

In addition, in another comparative example, a through hole is formed using a machine drill to minimize a difference between a minimum width and a maximum width. However, when a machine drill is used, only one through hole can be formed at a time. This causes a problem of lowering the production yield.

In contrast, the embodiment forms a through hole in the first insulating layer using at least two coordinate codes (T-codes). According to the embodiment, it is possible to change the laser process conditions during a process of forming the through hole by using two coordinate codes according to energy intensities. According to the embodiment, a part of the through hole is formed by irradiating a laser with a first laser energy intensity to a first mask having an opening of a first size using a first coordinate code. Furthermore, a remain part of the through hole is formed by irradiating a laser with a second laser energy intensity having an energy intensity different from the first laser energy intensity to a second mask having an opening of a second size different from the first size using a second coordinate code. Through this, the embodiment can form a through hole with a minimum difference between the maximum width and the minimum width in the first insulating layer using laser equipment while preventing the size expansion of the through hole. Accordingly, the embodiment can solve the unevenness of a thickness of the first through electrode in a plating process of arranging the first through electrode in the first through hole. In addition, it is possible to solve a physical problem in which the first through electrode is peeled off from the first insulating layer or cracks occur in the first through electrode. Through this, the embodiment can improve physical characteristics of the semiconductor package substrate. As described above, the embodiment may allow the first through electrode having a uniform thickness to be disposed in the first insulating layer by improving plating characteristics. Accordingly, a loss of a signal transmitted through the first through electrode may be minimized, a voltage drop may be prevented, and a degree of freedom in wiring design may be increased as it is advantageous for impedance matching. Furthermore, a first through hole according to the present embodiment may improve electrical characteristics of a semiconductor package substrate and semiconductor package including the same.

In addition, the embodiment may form a through hole using laser equipment in a first insulating layer including reinforcing fibers therein while having a thickness in a vertical direction of 250 μm to 1200 μm. Accordingly, the embodiment may reduce a time required to form the through hole compared to forming the through hole using machine drill equipment. Accordingly, the embodiment may improve the production yield of the semiconductor package substrate. Furthermore, the embodiment may form through holes in all insulating layers of a multilayer substrate including a core layer using only laser equipment. Accordingly, the embodiment may improve the efficiency in a manufacturing process of the semiconductor package substrate. Furthermore, the embodiment may reduce the manufacturing cost of the semiconductor package substrate by not having to use relatively expensive machine drill equipment.

### DESCRIPTION OF DRAWINGS

FIG. 1a is a cross-sectional view for explaining a semiconductor package substrate according to a first comparative example

FIG. 1b is a cross-sectional view for explaining a semiconductor package substrate according to a second comparative example.

FIG. 2a is a cross-sectional view showing a semiconductor package according to a first embodiment.

FIG. 2b is a cross-sectional view showing a semiconductor package according to a second embodiment.

FIG. 2c is a cross-sectional view showing a semiconductor package according to a third embodiment.

FIG. 2d is a cross-sectional view showing a semiconductor package according to a fourth embodiment.

FIG. 2e is a cross-sectional view showing a semiconductor package according to a fifth embodiment.

FIG. 2f is a cross-sectional view showing a semiconductor package according to a sixth embodiment.

FIG. 2g is a cross-sectional view showing a semiconductor package according to a seventh embodiment.

FIG. 3a is a view illustrating a semiconductor package substrate according to a first embodiment.

FIG. 3b is a view illustrating a semiconductor package substrate according to a second embodiment.

FIG. 4 is a cross-sectional view for explaining a first insulating layer of an embodiment.

FIG. 5 is a cross-sectional view showing a first through hole provided in a first insulating layer of FIG. 4.

FIG. 6 is a cross-sectional view showing a first through electrode and an insulating member disposed in a through hole of FIG. 5.

FIG. 7 is a view showing a layer structure of a first through electrode and a first circuit pattern layer according to a first embodiment.

FIG. 8 is a view showing a layer structure of a first through electrode and a first circuit pattern layer of a second embodiment.

FIG. 9 is an optical micrograph of an actual product including a first through hole, a first through electrode, and an insulating member according to an embodiment.

FIGS. 10 to 14 are views showing a part of a method of manufacturing a semiconductor package substrate according to an embodiment in order of processes.

### BEST MODE

Hereinafter, embodiments of the present disclosure will be described in detail with reference to the accompanying drawings.

However, the spirit and scope of the present disclosure is not limited to a part of the embodiments described, and may be implemented in various other forms, and within the spirit and scope of the present disclosure, one or more of the elements of the embodiments may be selectively combined and redisposed.

In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art. In addition, the terms used in the embodiments of the present disclosure are for describing the embodiments and are not intended to limit the present disclosure.

In this specification, the singular forms may also include the plural forms unless specifically stated in the phrase, and may include at least one of all combinations that may be combined in A, B, and C when described in “at least one (or more) of A (and), B, and C”. Further, in describing the elements of the embodiments of the present disclosure, the terms such as first, second, A, B, (a), and (b) may be used.

These terms are only used to distinguish the elements from other elements, and the terms are not limited to the essence, order, or order of the elements. In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements. Further, when expressed as “on (over)” or “under (below)”, it may include not only the upper direction but also the lower direction based on one element.

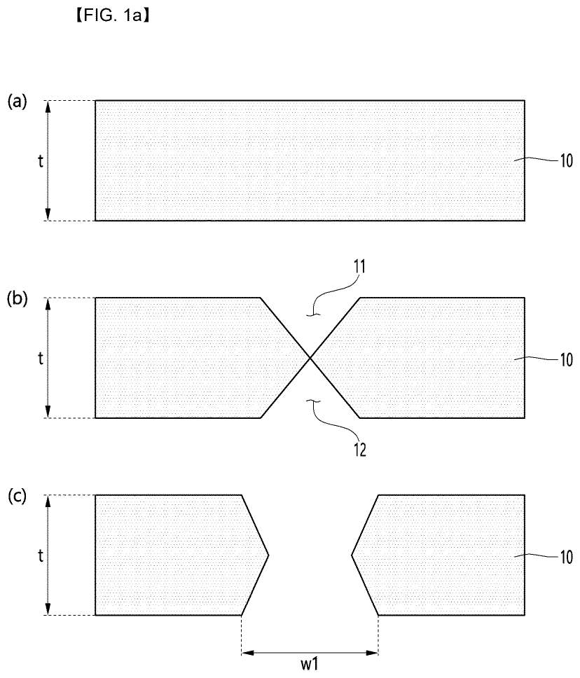

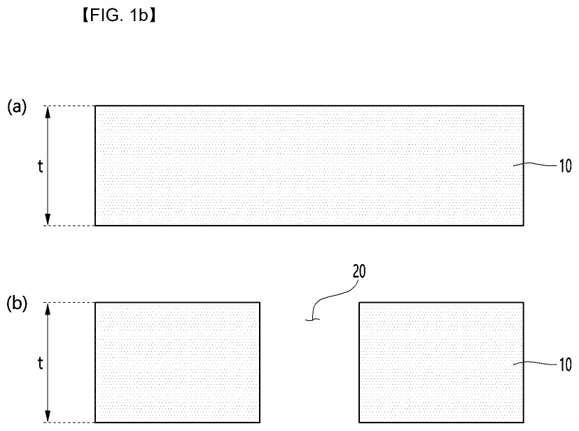

FIG. 1a is a cross-sectional view for explaining a semiconductor package substrate according to a first comparative example, and FIG. 1b is a cross-sectional view for explaining a semiconductor package substrate according to a second comparative example.

Before explaining a comparative example, a semiconductor package substrate is required to be denser due to the high functionality of electronic devices and high integration of semiconductor devices. Accordingly, the semiconductor package substrate has a multilayer structure.

A product group to which this multilayer structure semiconductor package substrate is applied includes FCBGA (Flip Chip Ball Grid Array) or FCCSP (Flip-Chip Chip Scale Package). In addition, some semiconductor package substrates applied to FCBGA or FCCSP include a core layer.

The core layer is an insulating layer that has rigidity for implementing multilayer build-up and has a thickness greater than a certain level. A thickness of the core layer may vary depending on the number of layers according to the multilayer build-up. For example, a wiring of the semiconductor package substrate may become complicated, and accordingly, a thickness may be 250 μm to 1200 μm in order to reduce voltage drop problems and/or signal loss.

In addition, a through electrode is formed in the core layer for electrical conductivity with a circuit pattern of each layer. The through electrode may be provided by filling a through hole passing through upper and lower surfaces of the core layer with a conductive material. However, the core layer described above has a thickness of 250 μm to 1200 μm, and accordingly, a process of forming a through hole and/or the process of forming a through electrode of the comparative example have the following problems.

The through hole is formed using either laser equipment or drill machine equipment. FIG. 1a shows a first comparative example of forming a through hole using laser equipment, and FIG. 1b shows a second comparative example of forming through hole using drill machine equipment.

As in (a) of FIG. 1a, in the first comparative example, an insulating layer 10 to be used as a core layer is prepared. At this time, a thickness (t) of the insulating layer 10 may be 250 μm to 1200 μm.

In addition, in the first comparative example, a through hole is formed in the insulating layer 10 using laser equipment.

At this time, since the insulating layer 10 has a thickness (t) of 250 μm to 1200 μm, it is difficult to form a through hole by performing laser processing on only one side of the insulating layer 10. Accordingly, in the first comparative example, a through hole is formed by performing laser processing on each of the upper and lower surfaces of the insulating layer 10.

Specifically, the first comparative example forms a first portion of the through hole at the upper surface of the insulating layer 10 to correspond to a target size that the through hole should have, and forms a second portion connected to the first portion of the through hole at the lower surface of the insulating layer 10.

However, as in (b) of FIG. 1a, when an energy intensity of the laser is set to correspond to a target size, the energy intensity of the laser is small compared to a thickness of the insulating layer 10, and when the first portion 11 and the second portion 12 are formed as described above, a non-passing problem may occur in which the first portion 11 and the second portion 12 are not connected to each other.

Accordingly, in the first comparative example, the energy intensity of the laser is set to a great value in order to solve the non-passing problem of the insulating layer 10 described above. Therefore, as in (c) of FIG. 1a, it is formed with a first portion 11 and a second portion 12 having a size larger than the target size that the through hole should have.

However, in this case, the through hole has a width w1 larger than the target size. Accordingly, there is a problem that it is difficult to match a size of the through hole and the through electrode formed by filling the through hole in the first comparative example to a desired target size.

Furthermore, in the first comparative example, as the size of the through hole increases, problems such as voids (a phenomenon in which a part of the through hole is not filled) or dimples may occur due to differences in plating speeds during a process of filling the inside of the through hole with a conductive material.

In addition, the first comparative example irradiates a laser beam multiple times using one coordinate code (e.g., T-code) to a specific through hole. In this case, since the first comparative example uses one coordinate code, it is impossible to change laser process conditions while multiple steps are in progress. Here, the laser process conditions may mean a mask size, a pulse width, an energy intensity, a collimation, and a number of steps.

Accordingly, in the first comparative example, when an initially set laser process condition corresponds to the target size, a non-passing problem occurs. Furthermore, in the first comparative example, even if the through hole is formed by passing through the insulating layer 10, a minimum width in the entire region in the vertical direction of the through hole is less than 50% of a maximum width. In addition, as a difference between the minimum width and the maximum width increases, there is a problem that plating characteristics in a plating process for forming the through electrode deteriorate.

Referring to another conventional technology, as in (a) and (b) of FIG. 1b, the second comparative example forms a through hole 20 using a drill machine equipment such as a CNC (computer numerical control) drill rather than a laser.

When using the drill machine equipment, a slope of the inner wall of the through hole formed in the insulating layer 10 is substantially close to vertical.

However, since this through hole 20 does not include a plating bridge unlike the through hole of FIG. 1a having an hourglass shape, there is a problem that it is difficult to uniformly fill the conductive material within the through hole 20.

Furthermore, the drill machine equipment is expensive compared to the laser equipment. Therefore, when forming a through hole using a drill machine, there is a problem that a large cost is required for infrastructure construction or the manufacturing cost of the semiconductor package substrate increases.

In addition, when forming a through hole 20 using a drill machine, there is a problem that the productivity of the semiconductor package substrate decreases. Specifically, when using a drill machine, only one through hole can be formed at a time. Accordingly, the manufacturing process time of the semiconductor package substrate may increase several times more than when using a laser equipment, and there is a problem that the productivity or yield decreases accordingly.

However, when forming a through hole using a laser equipment according to a present embodiment, a plurality of through holes can be formed at a time using openings included in a mask, and a uniform through electrode can be formed in each of the plurality of through holes. In addition, the manufacturing process time of the semiconductor package substrate can be significantly shortened compared to when using a drill machine, and thus the productivity or yield can be significantly improved.

The embodiment allows for forming a through electrode with improved electrical and physical reliability within a through hole formed in a core layer having a thickness of 250 μm to 1200 μm. For example, the embodiment allows for providing a semiconductor package substrate including a through electrode having a novel structure and a package substrate including the same.

### Electronic Device

Before describing the embodiment, an electronic device to which the semiconductor package of the embodiment is applied will be briefly described.

An electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

The electronic device includes a main board (not shown). The main board may be physically and/or electrically connected to various components. In addition, the main board may be connected to the semiconductor package substrate of the embodiment. Various semiconductor devices may be mounted on the semiconductor package substrate.

The semiconductor device may include an active device and/or a passive device. The active device may be a semiconductor chip in the form of an integrated circuit (IC) in which hundreds to millions of devices are integrated in one semiconductor device. The semiconductor device may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far.

The memory chip may be a stack memory such as HBM. The memory chip may also include a memory chip such as volatile memory (e.g., DRAM), non-volatile memory (e.g., ROM), flash memory, and the like.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

Hereinafter, a semiconductor package including a semiconductor package substrate according to an embodiment will be described. The semiconductor package of the embodiment may have various package structures including a semiconductor package substrate to be described later. In addition, the semiconductor package substrate in one embodiment may be referred to as a first semiconductor package substrate described below, and the semiconductor package substrate in another embodiment may be referred to as a second semiconductor package substrate described below.

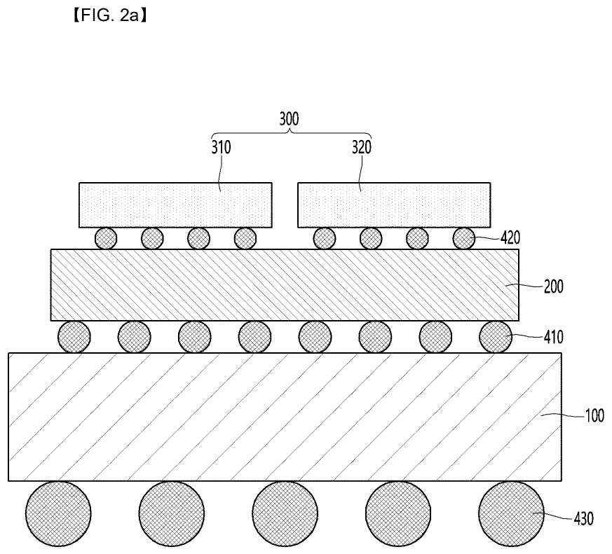

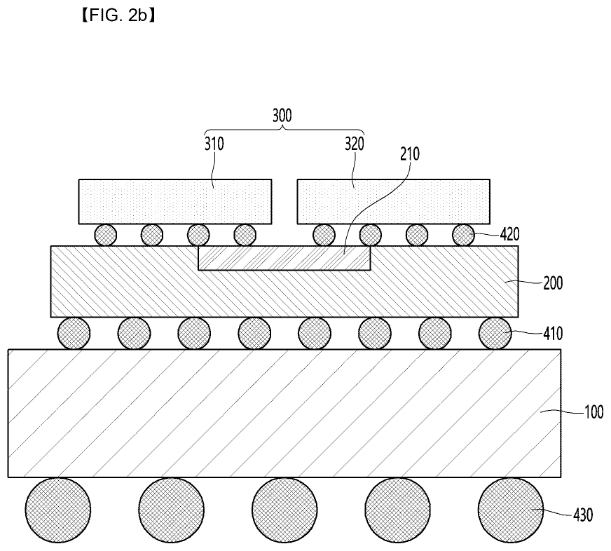

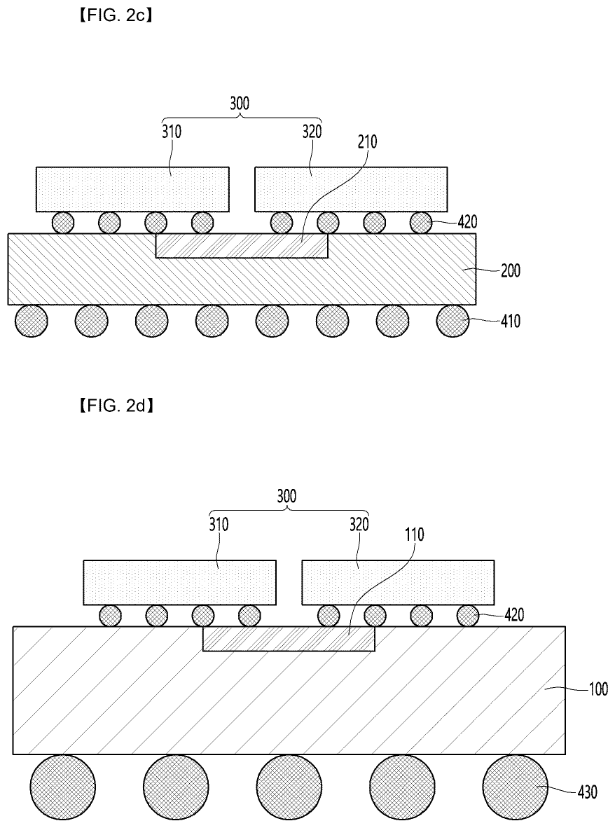

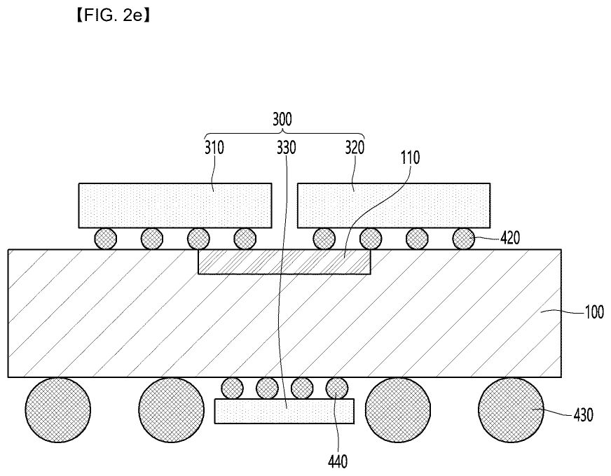

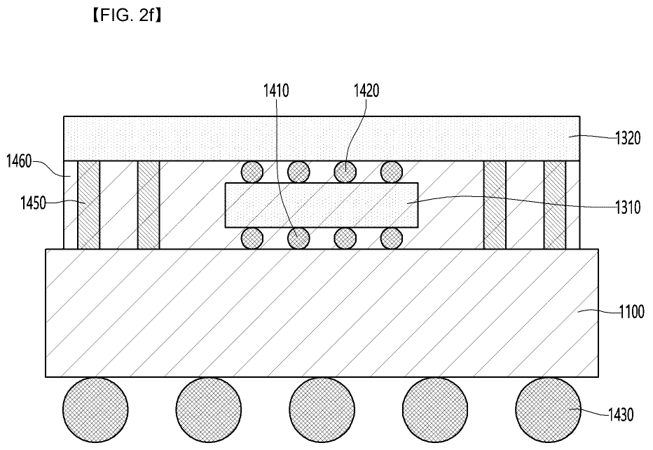

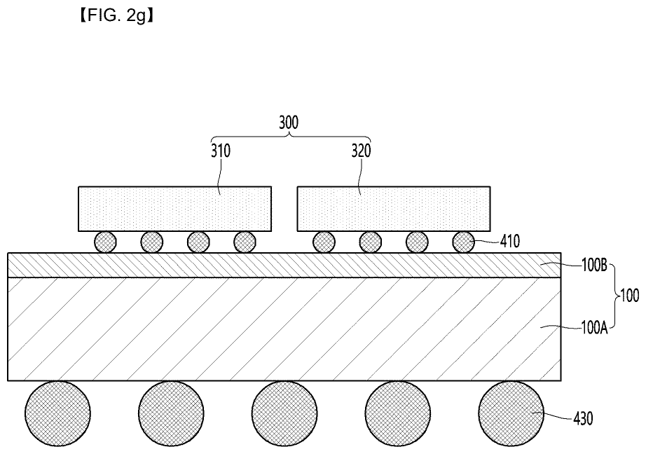

FIG. 2a is a cross-sectional view showing a semiconductor package according to a first embodiment, FIG. 2b is a cross-sectional view showing a semiconductor package according to a second embodiment. FIG. 2c is a cross-sectional view showing a semiconductor package according to a third embodiment, FIG. 2d is a cross-sectional view showing a semiconductor package according to a fourth embodiment, FIG. 2e is a cross-sectional view showing a semiconductor package according to a fifth embodiment, FIG. 2f is a cross-sectional view showing a semiconductor package according to a sixth embodiment, and FIG. 2g is a cross-sectional view showing a semiconductor package according to a seventh embodiment.

Referring to FIG. 2a, the semiconductor package of the first embodiment may include a first semiconductor package substrate 100, a second semiconductor package substrate 200, and a semiconductor device 300.

The first semiconductor package substrate 100 means a package substrate.

For example, the first semiconductor package substrate 100 may provide a space in which at least one external substrate is coupled. The external substrate may mean a second semiconductor package substrate 200 coupled on the first semiconductor package substrate 100. In addition, the external substrate may mean a main board included in an electronic device coupled to a lower portion of the first semiconductor package substrate 100.

In addition, although not shown in the drawing, the first semiconductor package substrate 100 may provide a space in which at least one semiconductor device is mounted in addition to a space in which the second semiconductor package substrate 200 is mounted.

The first semiconductor package substrate 100 includes at least one insulating layer, an electrode disposed on the at least one insulating layer, and a through part passing through the at least one insulating layer.

A second semiconductor package substrate 200 is disposed on the first semiconductor package substrate 100.

For example, the second semiconductor package substrate 200 may be an interposer. In addition, the second semiconductor package substrate 200 may provide a space in which at least one semiconductor device is mounted. The second semiconductor package substrate 200 may be connected to at least one semiconductor device 300. For example, the second semiconductor package substrate 200 may provide a space in which a first semiconductor device 310 and/or a second semiconductor device 320 are mounted. The second semiconductor package substrate 200 can electrically connect the first semiconductor device 310 and the second semiconductor device 320, and electrically connect the first and second semiconductor devices 310 and 320 and the first semiconductor package substrate 100. That is, the second semiconductor package substrate 200 can perform a horizontal connection function between a plurality of semiconductor devices and a vertical connection function between the semiconductor device and a package substrate. In addition, in order to improve stress and warpage problems that occur due to an increase in a number of laminated insulating layers by multilayer build-up, the semiconductor package substrate can be divided into the first semiconductor package substrate 100 and the second semiconductor package substrate 200.

In FIG. 2a, two semiconductor devices 310 and 320 are illustrated as being disposed on the second semiconductor package substrate 200, but the embodiment is not limited thereto. For example, one semiconductor device may be disposed on the second semiconductor package substrate 200, or alternatively, three or more semiconductor devices may be disposed on the second semiconductor package substrate 200.

In one embodiment, the second semiconductor package substrate 200 may be an active interposer that functions as a semiconductor device. When the second semiconductor package substrate 200 functions as an active circuit, a package of the embodiment may have multiple logic chips mounted so as to be vertically stacked on the first semiconductor package substrate 100. In addition, a first logic chip corresponding to the active interposer among the logic chips may perform a function of a corresponding logic chip while performing a signal transmission function between a second logic chip disposed on the first logic chip and the first semiconductor package substrate 100.

According to another embodiment, the second semiconductor package substrate 200 may be a passive interposer. For example, the second semiconductor package substrate 200 may perform a signal relay function between the semiconductor device 300 and the first semiconductor package substrate 100. For example, the number of terminals in a semiconductor device 300 is gradually increasing due to reasons such as 5G, the Internet of Things (IoT), increased picture quality, and increased communication speed. In other words, a number of terminals provided in the semiconductor device 300 is increasing, and accordingly, a width of the terminals or a spacing between multiple terminals is decreasing. At this time, the first semiconductor package substrate 100 is connected to the main board of the electronic device. Accordingly, in order for the electrodes provided on the first semiconductor package substrate 100 to have a width and spacing for connecting to the semiconductor device 300 and the main board, respectively, there is a problem that a thickness of the first semiconductor package substrate 100 increases or a layer structure of the first semiconductor package substrate 100 becomes complicated. Therefore, in the first embodiment, the second semiconductor package substrate 200 is disposed on the first semiconductor package substrate 100 and the semiconductor device 300. In addition, the second semiconductor package substrate 200 may include an electrode having a fine width and a fine spacing corresponding to the terminal of the semiconductor device 300.

Meanwhile, the semiconductor package of the first embodiment may include a connection part.

For example, the semiconductor package includes a first connection part 410 disposed between the first semiconductor package substrate 100 and the second semiconductor package substrate 200. The first connection part 410 electrically connects the first semiconductor package substrate 100 and the second semiconductor package substrate 200 while being coupled to the first semiconductor package substrate 100.

For example, the semiconductor package may further include a second connection part 420 disposed between the second semiconductor package substrate 200 and the semiconductor device 300. The second connection part 420 may electrically connect the semiconductor device 300 while being coupled to the second semiconductor package substrate 200.

The semiconductor package includes a third connection part 430 disposed on a lower surface of the first semiconductor package substrate 100. The third connection part 430 can electrically connect the first semiconductor package substrate 100 to a main board while being coupled to the first semiconductor package substrate 100.

At this time, the first connection part 410, the second connection part 420, and the third connection part 430 may mean at least one bonding method among wire bonding, solder bonding, and direct bonding between metals. That is, since the first connection part 410, the second connection part 420, and the third connection part 430 have a function of electrically connecting a plurality of components, when direct bonding between metals is used, the connection parts may be understood as a part that is electrically connected, not a solder or a wire.

The wire bonding method may mean electrically connecting a plurality of components using a conductor such as gold (Au). In addition, the solder bonding method may electrically connect a plurality of c components using a material including at least one of Sn, Ag, and Cu. In addition, the direct bonding method between metals may mean directly bonding a plurality of components by applying heat and pressure between a plurality of components without a solder, wire, conductive adhesive, etc. to recrystallize the metals. In addition, the direct bonding method between metals may mean a bonding method by the second connection part 420. In this case, the second connection part 420 may mean a metal layer formed between a plurality of components by recrystallization.

The first connection part 410, the second connection part 420, and the third connection part 430 may bond a plurality of components to each other by a thermal compression (TC) bonding method. The TC bonding may mean a method of bonding a plurality of components by applying heat and pressure to the first connection part 410, the second connection part 420, and the third connection part 430.

At this time, in at least one of the first semiconductor package substrate 100 and the second semiconductor package substrate 200, a protrusion may be disposed on an electrode on which the first connection part 410, the second connection part 420, and the third connection part 430 are disposed. The protrusion may protrude from the first semiconductor package substrate 100 or the second semiconductor package substrate 200 in an outward direction.

The protrusion may be referred to as a bump. The protrusion may also be referred to as a post. The protrusion may also be referred to as a pillar. Preferably, the protrusion may refer to an electrode on which a second connection part 420 for coupling with a semiconductor device 300 is disposed among the electrodes of the second semiconductor package substrate 200. That is, as a pitch of the terminals of the semiconductor device 300 becomes finer, a short circuit of the second connection part 420 connected to each terminal of the semiconductor device 300 may occur. Therefore, in order to reduce a volume of the second connection part 420, the embodiment includes a protrusion in an electrode of the second semiconductor package substrate 200 on which the second connection part 420 is disposed. The protrusion can improve the alignment between the electrode of the second semiconductor package substrate 200 and the terminal of the semiconductor device 300 and prevent diffusion of the second connection part 420.

Meanwhile, referring to FIG. 2b, the semiconductor package of the second embodiment is different from the semiconductor package of the first embodiment in that a connection member 210 is disposed in the second semiconductor package substrate 200 to horizontally connect a plurality of semiconductor devices disposed on the second semiconductor package substrate 200. The connection member 210 may be referred to as a bridge substrate.

In one embodiment, the connection member 210 may be a silicon bridge. That is, the connection member 210 may include a silicon substrate and a redistribution layer disposed on the silicon substrate.

In another embodiment, the connection member 210 may be an organic bridge. For example, the connection member 210 may include an organic material. For example, the connection member 210 may include an organic substrate containing an organic material instead of a silicon substrate and a redistribution layer disposed on the organic substrate.

The connection member 210 may be embedded in the second semiconductor package substrate 200, but is not limited thereto. For example, the connection member 210 may be disposed with a structure protruding on the second semiconductor package substrate 200.

In addition, the second semiconductor package substrate 200 may include a cavity, and the connection member 210 may be disposed in the cavity of the second semiconductor package substrate 200.

Referring to FIG. 2c, the semiconductor package of the third embodiment includes a second semiconductor package substrate 200 and a semiconductor device 300. At this time, the semiconductor package of the third embodiment has a structure in which the first semiconductor package substrate 100 is removed compared to the semiconductor package of the second embodiment.

That is, the second semiconductor package substrate 200 of the third embodiment can function as a package substrate while performing an interposer function.

The first connection part 410 disposed on the lower surface of the second semiconductor package substrate 200 can connect the second semiconductor package substrate 200 to the main board of the electronic device. Referring to FIG. 2d, the semiconductor package of the fourth embodiment includes a first semiconductor package substrate 100 and a semiconductor device 300.

At this time, the semiconductor package of the fourth embodiment has a structure in which the second semiconductor package substrate 200 is removed compared to the semiconductor package of the second embodiment.

That is, the first semiconductor package substrate 100 of the fourth embodiment can function as a package substrate while performing an interposer function connecting the semiconductor device 300 and the main board. To this end, the first semiconductor package substrate 100 can include a connection member 110 for connecting a plurality of semiconductor devices. The connection member 110 may be a silicon bridge or an organic bridge connecting a plurality of semiconductor devices.

Referring to FIG. 2e, the semiconductor package of the fifth embodiment further includes a third semiconductor device 330 compared to the semiconductor package of the fourth embodiment.

To this end, a fourth connection part 440 is disposed on the lower surface of the first semiconductor package substrate 100.

In addition, the third semiconductor device 330 may be disposed on the fourth connection part 400. That is, the semiconductor package of the fifth embodiment may have a structure in which semiconductor devices are mounted on upper and lower sides, respectively.

At this time, the third semiconductor device 330 may have a structure arranged on the lower surface of the second semiconductor package substrate 200 in the semiconductor package of FIG. 2c.

Referring to FIG. 2f, the semiconductor package of the sixth embodiment includes a first semiconductor package substrate 100.

A first semiconductor device 310 may be disposed on the first semiconductor package substrate 100. To this end, a first connection part 410 is disposed between the first semiconductor package substrate 100 and the first semiconductor device 310.

In addition, the first semiconductor package substrate 100 includes a conductive bonding part 450. The conductive bonding part 450 may further protrude from the first semiconductor package substrate 100 toward the second semiconductor device 320. The conductive bonding part 450 may be referred to as a bump, or alternatively, as a post. The conductive bonding part 450 may be disposed with a protruding structure on an electrode disposed at an uppermost side of the first semiconductor package substrate 100.

A second semiconductor device 320 is disposed on the conductive bonding part 450 of the first semiconductor package substrate 100. At this time, the second semiconductor device 320 can be connected to the first semiconductor package substrate 100 through the conductive bonding part 450. In addition, a second connection part 420 can be disposed on the first semiconductor device 310 and the second semiconductor device 320.

Accordingly, the second semiconductor device 320 can be electrically connected to the first semiconductor device 310 through the second connection part 420.

That is, the second semiconductor device 320 is connected to the first semiconductor package substrate 100 through the conductive bonding part 450, and is also connected to the first semiconductor device 310 through the second connection part 420.

At this time, the second semiconductor device 320 can receive a power signal through the conductive bonding part 450. In addition, the second semiconductor device 320 can exchange a communication signal with the first semiconductor device 310 through the second connection part 420.

The semiconductor package of the sixth embodiment can provide sufficient power for driving the second semiconductor device 320 by providing a power signal to the second semiconductor device 320 through the conductive bonding part 450. Accordingly, the embodiment can improve driving characteristics of the second semiconductor device 320. That is, the embodiment can solve a problem of insufficient power provided to the second semiconductor device 320. Furthermore, the embodiment allows a power signal and a communication signal of the second semiconductor device 320 to be provided through different paths through the conductive bonding part 450 and the second connection part 420. Through this, the embodiment can solve a problem of loss of the communication signal occurring due to the power signal. For example, the embodiment can minimize mutual interference between the communication signal and the power signal. Meanwhile, the second semiconductor device 320 in the sixth embodiment can have a POP (Package On Package) structure and be disposed on the first semiconductor package substrate 100. For example, the second semiconductor device 320 can be a memory package including a memory chip. In addition, the memory package can be bonded on the conductive bonding part 450. At this time, the memory package may not be connected to the first semiconductor device 310. For example, in a case of the POP structure, the second connection part 420 can be omitted.

Meanwhile, the semiconductor package in the sixth embodiment can include a molding member 1460. The molding member 1460 can be disposed between the first circuit board 1100 and the second semiconductor device 1320. For example, the molding member 1460 can mold the first connection part 1410, the second connection part 1420, the first semiconductor device 1310, and the conductive bonding part 1450.

Referring to FIG. 2g, the semiconductor package of the seventh embodiment includes a first semiconductor package substrate 100, a first connection part 410, a first connection part 410, a semiconductor device 300, and a third connection part 430.

At this time, the semiconductor package of the seventh embodiment is different from the semiconductor package of the fourth embodiment in that the connection member 110 is removed, and the first semiconductor package substrate 100 includes a plurality of substrate layers.

The first semiconductor package substrate 100 includes a plurality of substrate layers. For example, the first semiconductor package substrate 100 may include a first substrate layer 100A corresponding to a package substrate and a second substrate layer 100B corresponding to a redistribution layer of a connection member.

That is, the first semiconductor package substrate 100 arranges the second substrate layer 100B corresponding to the redistribution layer on the first substrate layer 100A.

In other words, the semiconductor package of the seventh embodiment includes a semiconductor package substrate including a first substrate layer 100A and a second substrate layer 100B formed integrally. A material of the insulating layer of the second substrate layer 100B may be different from a material of the insulating layer of the first substrate layer 100A. For example, a material of the insulating layer of the second substrate layer 100B may include a photocurable material. For example, the second substrate layer 100B may be a PID (Photo Imageable Dielectric). In addition, since the second substrate layer 100B includes a photocurable material, an electrode can be miniaturized. Therefore, the seventh embodiment can form the second substrate layer 100B by sequentially stacking an insulating layer of a photocurable material on the first substrate layer 100A and forming a miniaturized electrode on the insulating layer of the photocurable material. Through this, the second substrate layer 100B can be a redistribution layer including a miniaturized electrode.

Hereinafter, the semiconductor package substrate of the embodiment will be described.

Before describing the semiconductor package substrate of the embodiment, the semiconductor package substrate described below may mean any one of a plurality of semiconductor package substrates included in a previous semiconductor package.

For example, the semiconductor package substrate described below in one embodiment may mean the first semiconductor package substrate 100 and/or the second semiconductor package substrate 200 illustrated in any one of FIGS. 2a to 2g.

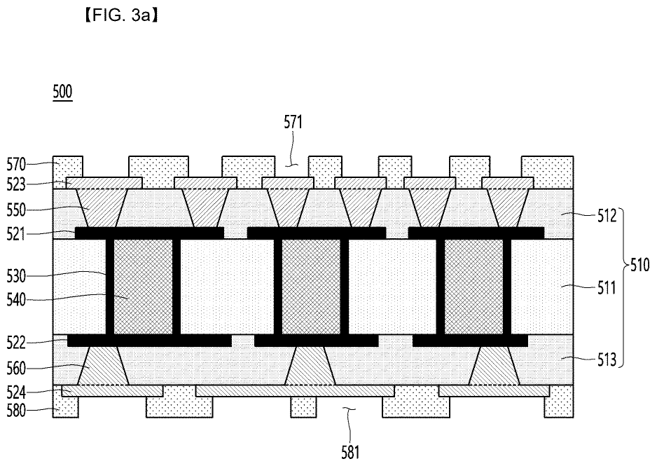

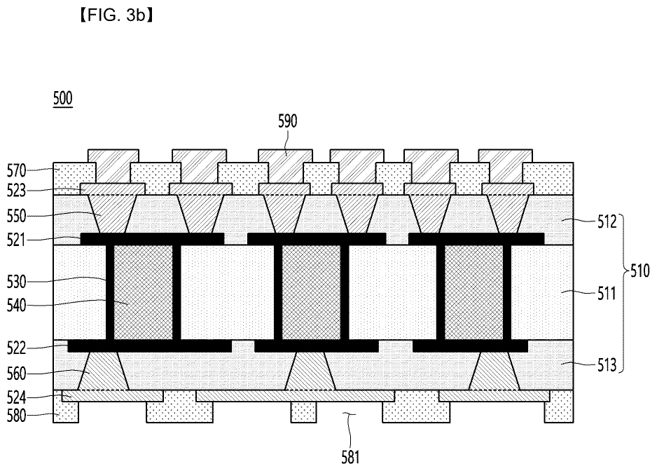

FIG. 3a is a view illustrating a semiconductor package substrate according to a first embodiment, and FIG. 3b is a view illustrating a semiconductor package substrate according to a second embodiment.

Hereinafter, a semiconductor package substrate according to the embodiment will be briefly described with reference to FIG. 3a, and some components different from FIG. 3a will be described with reference to FIG. 3b.

The semiconductor package substrate 500 of the embodiment includes an insulating layer 510. At this time, the insulating layer 510 of the embodiment may have a multilayer structure. For example, the insulating layer 510 of the semiconductor package substrate of the embodiment may include a first insulating layer 511, a second insulating layer 512, and a third insulating layer 513. In FIG. 3a, the second insulating layer 512 and the third insulating layer 513 are illustrated as one layer, but the present invention is not limited thereto and may have a configuration in which multiple insulating layers are laminated.

The first insulating layer 511 may include an insulating material different from insulating materials of the second insulating layer 512 and the third insulating layer 513.

For example, the first insulating layer 511 may include an insulating material including reinforcing fibers and may be a core layer.

For example, the first insulating layer 511 may include a prepreg. The first insulating layer 511 may increase a physical strength of the semiconductor package substrate and improve warpage characteristics.

The first insulating layer 511 of the embodiment may have a structure in which a fiber layer in a form of a fabric sheet, such as a glass fabric woven with glass fiber yarn, is impregnated with an epoxy resin or the like.

In addition, the prepreg constituting the first insulating layer 511 of the embodiment may include a fiber layer in the form of a fabric sheet woven with carbon fiber yarn.

Specifically, the first insulating layer 511 may include a resin and reinforcing fibers disposed in the resin. The resin may be an epoxy resin, but is not limited thereto. The resin is not particularly limited to an epoxy resin, and for example, in may contain one or more epoxy groups in a molecule, or alternatively, may contain two or more epoxy groups in a molecule, or alternatively, may contain four or more epoxy groups in a molecule. In addition, a resin constituting the first insulating layer 511 may contain a naphthalene group, and may be, for example, an aromatic amine type, but is not limited thereto. For example, a resin may include a bisphenol A type epoxy resin, a bisphenol F type epoxy resin, a bisphenol S type epoxy resin, a phenol novolac type epoxy resin, an alkylphenol novolac type epoxy resin, a biphenyl type epoxy resin, a aralkyl type epoxy resin, a dicyclopentadiene type epoxy resin, a naphthalene type epoxy resin, a naphthol type epoxy resin, an epoxy resin of a condensation product of phenols and aromatic aldehydes having a phenolic hydroxyl group, biphenyl aralkyl type epoxy resin, a fluorene type epoxy resin, a xanthene type epoxy resin, a triglycidyl isocyanurate, a rubber-modified epoxy resin, and a phosphorous epoxy resin, and may include a naphthalene type epoxy resin, a bisphenol A type epoxy resin, a phenol novolac epoxy resin, a cresol novolac epoxy resin, a rubber-modified epoxy resin, and a phosphorous epoxy resin. In addition, the reinforcing fibers may be glass fibers, carbon fibers, aramid fibers (e.g., organic materials of the aramid series), nylon, inorganic materials of silica series, or inorganic materials of titania series. The reinforcing fibers may be disposed in a form of intersecting each other in a plane direction within the resin.

Meanwhile, glass fibers, carbon fibers, aramid fibers (e.g., organic materials of the aramid series), nylon, inorganic materials of silica series, or inorganic materials of titania series may be used.

At this time, the first insulating layer 511 may be provided with at least two layers of reinforcing fibers. Through this, the embodiment may further improve a rigidity of the substrate 500.

A thickness of the first insulating layer 511 in a vertical direction may be greater than a thickness of at least one of the second insulating layer 512 and the third insulating layer 513 in the vertical direction. For example, the thickness of the first insulating layer 511 in the vertical direction may be 3 times or more, 4 times or more, 5 times or more, 7 times or more, or 10 times or more than the thickness of the second insulating layer 512 and the third insulating layer 513 in the vertical direction.

Recently, as the performance of semiconductor packages progresses, the number of insulating layers of the semiconductor package substrate is also increasing. For example, the number of insulating layers of the semiconductor package substrate may be 10 or more, 12 or more, 16 or more, or 20 or more. Specifically, when the second insulating layer 512 and the third insulating layer 513 are laminated in multiple layers, unlike as illustrated, the semiconductor package substrate may be warped due to the stress of each insulating layer. When the semiconductor package substrate is warped, it may be difficult to form a through electrode included in the semiconductor package substrate at an accurate position. In addition, when the semiconductor package substrate is warped, problems such as a position of the semiconductor device being misaligned in a process of mounting the semiconductor device on the semiconductor package substrate may occur. Therefore, in order to prevent warping of the semiconductor package substrate, the thickness of the first insulating layer 511 in the vertical direction may be 250 μm or more. Accordingly, in order to increase the physical rigidity of the semiconductor package substrate and improve warpage characteristics of the semiconductor package substrate in a packaging process, the first insulating layer 511 may have a thickness in the vertical direction of 250 μm or more. In addition, when the thickness of the first insulating layer 511 becomes too thick, a process of forming a through hole in the first insulating layer 511 becomes difficult, and electrical characteristics such as signals and/or power applied to the semiconductor device may deteriorate. In addition, since it may become difficult to make the semiconductor package slimmer, it may be difficult to provide a small volume of the electronic device. Therefore, it is appropriate that the thickness of the first insulating layer 511 in the vertical direction is 1200 μm or less.

The second insulating layer 512 and the third insulating layer 513 may include an insulating material different from that of the first insulating layer 511. For example, the second insulating layer 512 and the third insulating layer 513 may not include reinforcing fibers, but are not limited thereto.

For example, the second insulating layer 512 and the third insulating layer 513 may include any one of ABF (Ajinomoto Build-up Film), FR-4, BT (Bismaleimide Triazine), PID (Photo Imageable Dielectric resin), BT, etc.

In addition, the second insulating layer 512 and the third insulating layer 513 may include reinforcing fibers, and the reinforcing fibers may be glass fibers and may include GCP (Glass Core Primer) materials, but are not limited thereto.

In addition, the second insulating layer 512 and the third insulating layer 513 may use an insulating layer of a CCL (Copper Clad Laminate) type, but are not limited thereto.

The second insulating layer 512 and the third insulating layer 513 may have a thickness in the vertical direction in a range of 10 μm to 50 μm. If the thickness of the second insulating layer 512 or the third insulating layer 513 in the vertical direction is less than 10 μm, the warpage characteristics of the semiconductor package substrate 500 may deteriorate. In addition, if the thickness of the second insulating layer 512 or the third insulating layer 513 in the vertical direction is less than 10 μm, a circuit pattern layer included in the semiconductor package substrate 500 may not be stably protected or insulating characteristics may deteriorate, and thus the electrical reliability may deteriorate. In addition, if the thickness of the second insulating layer 512 or the third insulating layer 513 in the vertical direction exceeds 50 μm, an overall thickness of the semiconductor package substrate 500 increases, and accordingly, a thickness of the semiconductor package may increase. In addition, if the thickness of the second insulating layer 512 or the third insulating layer 513 exceeds 50 μm, it may be difficult to miniaturize a circuit pattern layer of the semiconductor package substrate 500.

The thickness in the vertical direction may mean a length in a direction from an upper surface to a lower surface or from a lower surface to an upper surface of the semiconductor package substrate 500. Here, the upper surface may mean a highest position along the vertical direction in each component, and the lower surface may mean a lowest position along the vertical direction in each component. In addition, their positions may be referred to as opposite to each other.

Meanwhile, in the drawing, the second insulating layer 512 and the third insulating layer 513 are each illustrated as being composed of 1 layer, but this is not limited thereto. For example, the semiconductor package substrate 500 of the embodiment may have a structure of 11 layers based on the number of insulating layers. In this case, the second insulating layer 512 and the third insulating layer 513 may each be composed of 5 layers. For example, the semiconductor package substrate 500 of the embodiment may have a structure of 17 layers based on the number of insulating layers. In this case, each of the second insulating layer 512 and the third insulating layer 513 may be composed of 8 layers.

The semiconductor package substrate 500 may include a circuit pattern layer disposed on the insulating layer 510.

The semiconductor package substrate 500 may include a first circuit pattern layer 521 disposed on an upper surface of the first insulating layer 511. The semiconductor package substrate 500 may include a second circuit pattern layer 522 disposed on a lower surface of the first insulating layer 511. The semiconductor package substrate 500 may include a third circuit pattern layer 523 disposed on an upper surface of the second insulating layer 512. The semiconductor package substrate 500 may include a fourth circuit pattern layer 524 disposed on a lower surface of the third insulating layer 513.

Among the circuit pattern layers, the third circuit pattern layer 523 disposed at an uppermost side may include an electrode pattern on which a semiconductor device is disposed. At this time, as illustrated in FIG. 3b, the semiconductor package substrate may include a protrusion 590 disposed on the electrode pattern of the third circuit pattern layer 523 and protruding toward the semiconductor device. The protrusion 590 may be referred to as a bump. The protrusion 590 may also be referred to as a post. The protrusion 590 may also be referred to as a pillar. That is, as a pitch of the terminal of the semiconductor device becomes finer, TC (Thermal Compression) bonding may be used, which applies heat and pressure to a conductive adhesive disposed between the electrode pattern and the terminal of the semiconductor device to bond them. When the TC (Thermal Compression) bonding is used, the protrusion 590 may also have a function of ensuring alignment between the electrode pattern and the terminal of the semiconductor device and preventing diffusion of the conductive adhesive. In addition, since a volume of the conductive adhesive disposed on each of the plurality of terminals can be reduced, an electrical short circuit problem due to a fine terminal pitch can be prevented. Here, solder may be used as the conductive adhesive, but is not limited thereto.

The circuit pattern layers 521, 522, 523, and 524 may include at least one metal material selected from gold (Au), silver (Ag), platinum (Pt), titanium (Ti), tin (Sn), copper (Cu), and zinc (Zn). The circuit pattern layers 521, 522, 523, and 524 may include a paste or solder paste including at least one metal material selected from gold (Au), silver (Ag), platinum (Pt), titanium (Ti), tin (Sn), copper (Cu), and zinc (Zn) having excellent bonding strength. Preferably, the circuit pattern layers 521, 522, 523, and 524 may be formed of copper (Cu) that has high electrical conductivity and is relatively inexpensive.

The circuit pattern layers 521, 522, 523, and 524 may have a thickness in a range of 10 μm to 25 μm. The thickness of the circuit pattern layers 521, 522, 523 and 524 may mean a thickness in a vertical direction.

If the thickness of the circuit pattern layers 521, 522, 523, and 524 is less than 10 μm, the resistance of the circuit pattern layers 521, 522, 523, and 524 may increase and an allowable current of a transmittable signal may decrease. In addition, if the thickness of the circuit pattern layers 521, 522, 523, and 524 exceeds 25 μm, it may be difficult to miniaturize the circuit pattern layers 521, 522, 523, and 524. If the thickness of the circuit pattern layers 521, 522, 523, and 524 exceeds 25 μm, the thickness of the insulating layer 510 must increase correspondingly, and as described above, the thickness of each insulating layer must be thickened for an insulating function and/or a protective function of the insulating layer. Accordingly, the thickness of the semiconductor package substrate and the semiconductor package may increase and it may become difficult to alleviate the warpage of the semiconductor package substrate.

The circuit pattern layers 521, 522, 523, and 524 may include a pad connected to a through electrode of the semiconductor package substrate 500, and at least one electrode pattern connected to an external substrate or a semiconductor device. In addition, the circuit pattern layers 521, 522, 523, and 524 may include traces of signal transmission lines connected to pads or electrode patterns.

The circuit pattern layers 521, 522, 523, and 524 may be manufactured by a conventional semiconductor package substrate manufacturing process, such as an additive process, a subtractive process, a modified semi-additive process (MSAP), and a semi-additive process (SAP), and a detailed description thereof is omitted herein.

The semiconductor package substrate 500 may include a first through electrode 530 passing through the first insulating layer 511, For example, the first insulating layer 511 may include a first through hole passing through the upper surface and the lower surface. In addition, the first through electrode 530 may be provided to fill at least a portion of the first through hole of the first insulating layer 511. In addition, the semiconductor package substrate 500 may be provided with an insulating member 540 that fills a remaining portion of the first through hole of the first insulating layer 511, and may be disposed to improve the flatness of the first circuit pattern layer 521 when the first through electrode 530 does not entirely fill the first through hole, and the first through electrode 530 may be disposed between the insulating member 540 and the first insulating layer 511. The insulating member 540 may be referred to as a hole plugging layer. The insulating member 540 may include an insulating material. For example, the insulating member 540 may be a paste of an insulating ink material. For example, the insulating member 540 may be a plugging ink. However, the embodiment is not limited thereto. For example, the insulating member 540 may include a conductive material. For example, the insulating member 540 may include a conductive paste containing a conductive metal powder.

The semiconductor package substrate 500 may include a second through electrode 550 passing through the second insulating layer 512. For example, the second insulating layer 512 may include a second through hole passing through the upper surface and the lower surface. In addition, the second through electrode 550 may be provided to entirely fill the second through hole of the second insulating layer 512.

The semiconductor package substrate 500 may include a third through electrode 560 passing through the third insulating layer 513. For example, the third insulating layer 513 may include a third through hole passing through the upper surface and the lower surface. In addition, the third through electrode 560 may be provided to entirely fill the third through hole of the third insulating layer 513.

The first through electrode 530, the second through electrode 550, and the third through electrode 560 may have different shapes.

The first through hole, the second through hole, and the third through hole may have different shapes. Accordingly, a slope of the first through electrode 530 surrounding the insulating member 540 disposed in the first through hole, a slope of the second through electrode 550, and a slope of the third through electrode 560 may be different from each other. For example, an slope of a side surface of the first through electrode 530, an slope of a side surface of the second through electrode 550, and an slope of a side surface of the third through electrode 560 may be different from each other. For example, a vertical cross-sectional shape of the first through electrode 530, a vertical cross-sectional shape of the second through electrode 550, and a vertical cross-sectional shape of the third through electrode 560 may be different from each other.

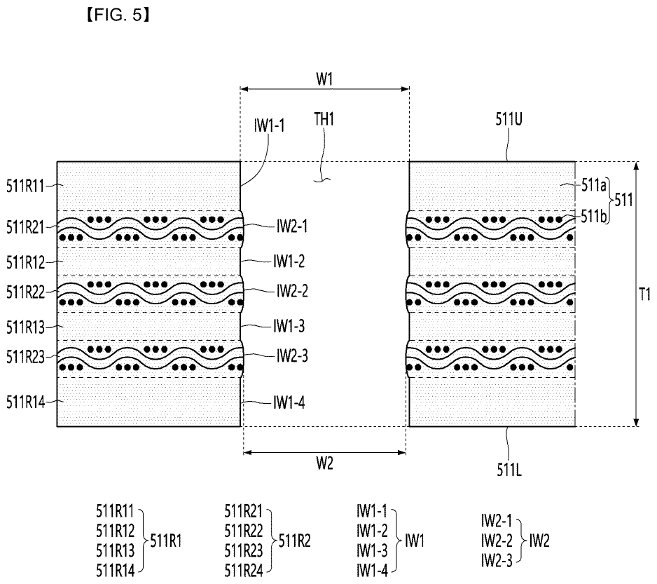

For a moment, referring to FIG. 5, an inner wall of the first through hole may include a plurality of concave portions and convex portions, and the concave portions and convex portions may be provided in a structure in which and the concave portions and convex portions are alternately stacked along the vertical direction. Here, the convex portion means a region that is protruding and/or convex toward a center of a horizontal direction of the first through hole, and the concave portion means a region that is concave in a opposite direction.

Unlike this, the second through hole may have a shape whose width decreases from an upper side to a lower side. In addition, the second through hole may be disposed so as not to include a plurality of concave portions and convex portions, unlike the first through hole.

In addition, the third through hole may have a shape whose width increases from an upper side to a lower side. In addition, the third through hole may be disposed so as not to include a plurality of concave portions and convex portions. In addition, the third through hole may have a symmetrical shape with the second through hole based on the first insulating layer 511, but is not limited thereto.

At this time, a thickness of the first through electrode 530 in the vertical direction, a depth of the first through hole, and further the thickness of the insulating member 540 in the vertical direction may correspond to a thickness of the first insulating layer 511. Accordingly, the thickness of the first through electrode 530 in the vertical direction, a depth of the first through hole, and the thickness of the insulating member in the vertical direction 540 may be 250 μm to 1200 μm.

In the embodiment, the first through hole is formed using a laser equipment in the first insulating layer 511, and a difference between a maximum width and a minimum width in the vertical direction of the first through hole can be minimized. Here, the vertical direction means a thickness direction from the upper surface to the lower surface of the first insulating layer 511.

According to a conventional technology, in order to minimize the difference between the maximum and minimum widths of the first through electrode 530, a drill machine equipment must be used as in the comparative example. However, as described above, when forming a through hole using a drill machine equipment, a slope of the inner wall of the through hole is close to vertical, so that the difference between the maximum and minimum widths of the first through electrode can be minimized, but there are problems such as decreased productivity, decreased yield, and increased process cost.

Therefore, the embodiment forms a through hole with a minimized difference between the maximum and minimum widths of the first insulating layer 511 using a laser equipment instead of a drill machine equipment.

To this end, the embodiment uses multiple coordinate codes (e.g., T-code) to form the first through hole in the first insulating layer 511. That is, when using the laser equipment, the comparative example forms a through hole in the core layer corresponding to the first insulating layer 511 using only one coordinate code. Accordingly, in a process of forming a through hole, it is difficult to change the laser process conditions during the process. Therefore, when forming a through hole by the laser equipment using only one coordinate code, the through hole has an hourglass shape in which the width gradually decreases from an upper portion and/or lower portion to a center, and thus a minimum width is less than 50% of a maximum width.

Unlike this, the embodiment forms the first through hole in the first insulating layer 511 using at least two coordinate codes.

In the embodiment, a part of the first through hole is formed in the first insulating layer 511 using a first coordinate code. Thereafter, the embodiment forms a remaining part of the first through hole connected to a part of the first through hole in the first insulating layer 511 using a second coordinate code. Through this, the embodiment can finally form the first through hole passing through the first insulating layer 511.

At this time, since the embodiment uses two coordinate codes, unlike the comparative example, laser process conditions can be changed during a process of forming the first through hole.

Accordingly, the embodiment can form a first through hole with a minimum difference between a maximum width and a minimum width using the laser equipment in the first insulating layer 511 corresponding to the core layer.

That is, the embodiment performs a first process of forming a part of the first through hole in the first insulating layer 511 using a first coordinate code, and a second process of forming a remaining part connected to a part of the first through hole in the first insulating layer 511 using a second coordinate code. At this time, in the first process using the first coordinate code, a first mask having an opening of a first size is used to form a part of the first through hole. The first size can correspond to a target size that the first through hole should have. Through this, the embodiment forms a part of the first through hole corresponding to the target size at each of the upper and lower surfaces of the first insulating layer 511 using the first mask.

Thereafter, the embodiment performs a second process using the second coordinate code after a part of the first through hole is formed. At this time, in the second process using the second coordinate code, a second mask having an opening of a second size different from the first size is used to form a remaining part of the first through hole. At this time, the second size is smaller than the first size. In the embodiment, in a second process of forming the remaining part of the first through hole using the second mask, an energy intensity of the laser is increased. Specifically, in a first process of forming a part of the first through hole using the first mask, the embodiment irradiates a laser having a first energy intensity to the first insulating layer 511. In addition, in the second process of forming the remaining part of the first through hole using the second mask, the embodiment irradiates a laser having a second energy intensity greater than the first energy intensity to the first insulating layer 511. At this time, a size of the opening provided in the second mask is smaller than the target size of the first through hole. That is, in the embodiment, a laser having a relatively small energy intensity is irradiated through an opening of a first mask having a first size, and a laser having a relatively large energy intensity is irradiated through an opening of a second mask having a second size smaller than the first size. Therefore, the embodiment can minimize a difference between a maximum width and a minimum width in the entire region in the vertical direction of the first through hole. In addition, the size of the opening of the second mask used when irradiating a laser having a relatively large energy intensity is smaller than the target size, and accordingly, the embodiment can prevent the size of the first through hole from expanding.

In conclusion, the embodiment allows forming a first through hole having a size corresponding to a target size and having an inner wall having a substantially vertical slope while utilizing the laser equipment through the above method.

This will be described in more detail below.

Again, referring to FIG. 3a, the semiconductor package substrate 500 of the embodiment includes a protective layer. The protective layer may also be referred to as an insulating layer or a resist layer. The protective layer refers to an insulating layer of an outermost layer of the semiconductor package substrate. The protective layer has a function of protecting a surface of the outermost layer of the semiconductor package substrate 500 and preventing short circuits between adjacent conductive adhesives. Accordingly, the protective layer may also be referred to as a ‘protective layer’ functionally. For example, when a conductive adhesive is used as a solder, the protective layer may be referred to as a solder resist.

Specifically, the protective layer includes a first protective layer 570 disposed on the upper surface of the second insulating layer 512. The first protective layer 570 includes at least one first opening 571 that vertically overlaps a portion of the third circuit pattern layer 523. The first opening 571 may be provided corresponding to a region where a conductive adhesive such as a connection part is to be disposed.

In addition, the protective layer includes a second protective layer 580 disposed on the lower surface of the third insulating layer 53. The second protective layer 580 includes at least one second opening 581 that vertically overlaps the fourth circuit pattern layer 524. The second opening 581 may be provided corresponding to a region where a conductive adhesive such as a connection part is to be disposed.

The first protective layer 570 and the second protective layer 580 may include an organic polymer material. For example, the first protective layer 570 and the second protective layer 580 may be solder protective layers. For example, the first protective layer 570 and the second protective layer 580 may include an epoxy acrylate series resin. In detail, the first protective layer 570 and the second protective layer 580 may include a resin, a curing agent, a photoinitiator, a pigment, a solvent, a filler, an additive, an acrylic series monomer, etc. However, the embodiment is not limited thereto. For example, the first protective layer 570 and the second protective layer 580 may include any one of a photo solder protective layer, a coverlay, and a polymer material.

The first protective layer 570 and the second protective layer 580 may have a thickness of 1 μm to 20 μm. At this time, if the thickness of the first protective layer 570 and the second protective layer 580 exceeds 20 μm, the overall thickness of the semiconductor package substrate and the overall thickness of the semiconductor package may increase, and as the stress increases, the warpage of the semiconductor package substrate may increase.

In addition, if the thickness of the first protective layer 570 and the second protective layer 580 is less than 1 μm, the circuit pattern layer may not be stably protected. If the thickness of the first protective layer 570 and the second protective layer 580 is less than 1 μm, the electrical reliability of the semiconductor package substrate and the electrical reliability of the semiconductor package may deteriorate.

Hereinafter, the first through hole, the first through electrode, and the insulating member formed in the first insulating layer 511 according to the embodiment will be described in more detail.

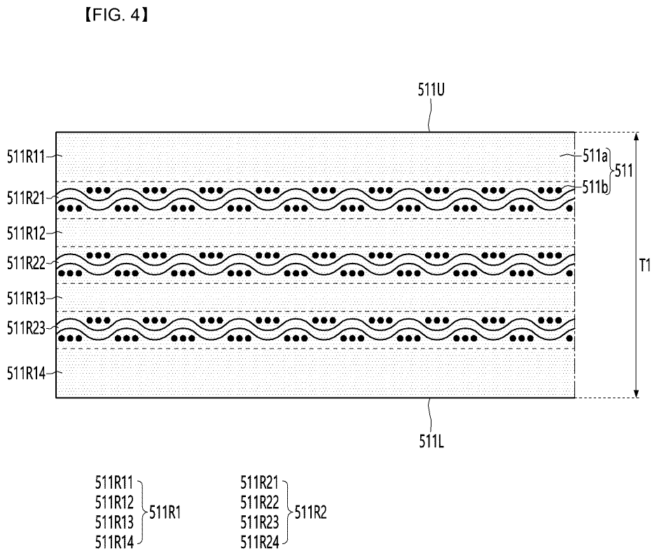

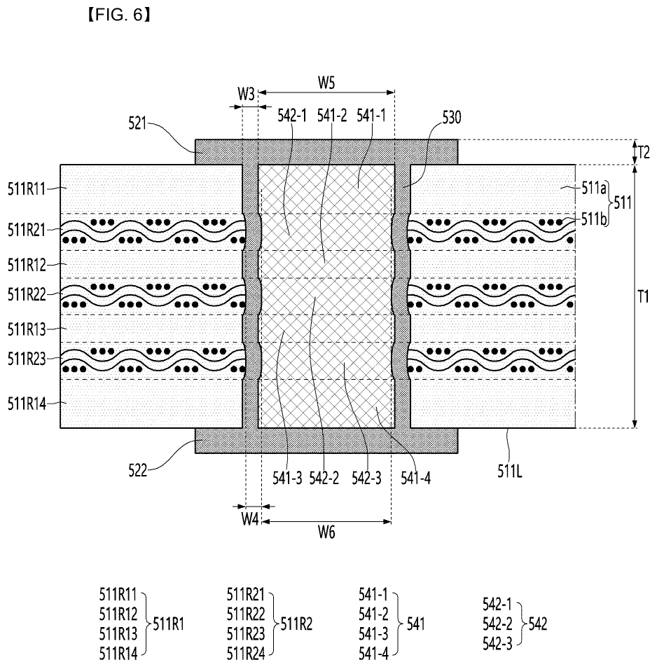

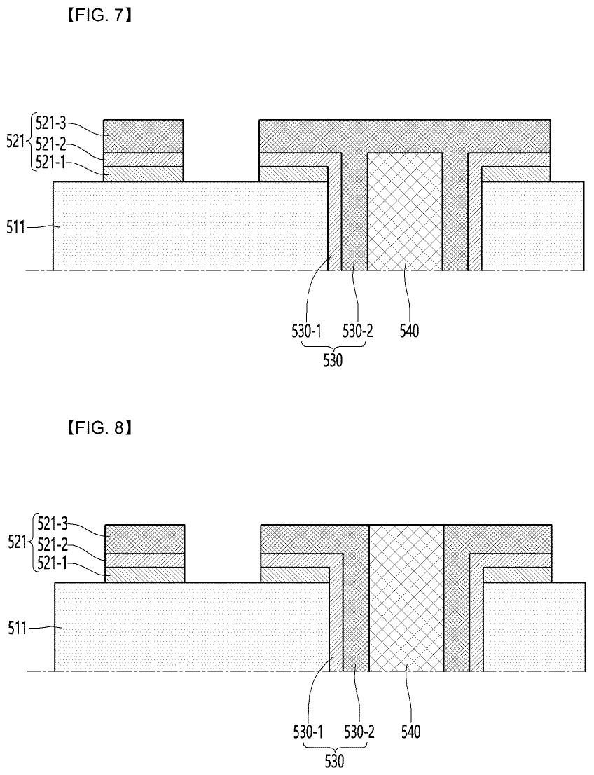

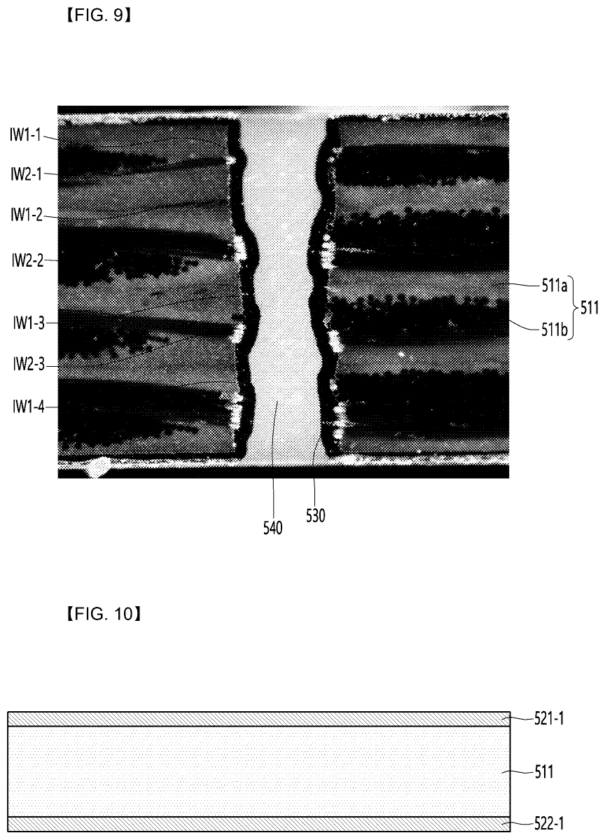

FIG. 4 is a cross-sectional view for explaining a first insulating layer of an embodiment, FIG. 5 is a cross-sectional view showing a first through hole provided in a first insulating layer of FIG. 4, FIG. 6 is a cross-sectional view showing a first through electrode and an insulating member disposed in a through hole of FIG. 5, FIG. 7 is a view showing a layer structure of a first through electrode and a first circuit pattern layer according to a first embodiment, FIG. 8 is a view showing a layer structure of a first through electrode and a first circuit pattern layer of a second embodiment, and FIG. 9 is an optical micrograph of an actual product including a first through hole, a first through electrode, and an insulating member according to an embodiment.

Hereinafter, the first through electrode 530, the first circuit pattern layer 521, the second circuit pattern layer 522, the first through electrode 530, and the insulating member 540 according to the embodiment will be described in detail with reference to FIGS. 4 to 9.

A thickness T1 in a vertical direction of the first insulating layer 511 of the embodiment can satisfy a range of 250 μm 1200 μm as described above.

At this time, referring to FIG. 4, the first insulating layer 511 can include a resin 511a and reinforcing fibers 511b disposed in the resin 511a.

The reinforcing fibers 511b can include a plurality of fibers disposed in different directions in the resin 511a. For example, the reinforcing fibers 511b include a first fiber disposed in a first horizontal direction and a second fiber disposed in a second horizontal direction perpendicular to the first horizontal direction. For example, among the reinforcing fibers 511b in FIG. 4, wave-shaped fibers can be the first fibers, and the dot-shaped fibers can be the second fibers.

The first fibers of the reinforcing fibers 511b can be called warp yarns. The second fiber of the reinforcing fiber 511b may be referred to as fill yarns.

That is, the reinforcing fiber 511b may be formed of a bundle of filaments, which are long glass fibers. In addition, the first fiber and the second fiber of the reinforcing fiber 511b may be disposed in first and second horizontal directions intersecting each other within the resin 511a, but are not limited thereto.

The reinforcing fiber 511b may be divided into a plurality of groups. For example, the reinforcing fiber 511b may be divided into a plurality of groups that are spaced apart from each other within the resin 511a of the first insulating layer 511 in the vertical direction.

For example, the reinforcing fiber 511b may include a first group to a third group separated from each other between an upper surface 511U and a lower surface 511L of the first insulating layer 511 in the vertical direction. Each of the first to third groups of reinforcing fibers is disposed in the first insulating layer 511 along a horizontal direction. In addition, the first to third groups of reinforcing fibers are mutually spaced apart in the vertical direction within the first insulating layer 511.

At this time, the drawing illustrates that the reinforcing fibers 511b are disposed in three groups within the first insulating layer 511, but is not limited thereto. For example, the number of groups of reinforcing fibers 511b may be determined based on a thickness of the first insulating layer 511 in the vertical direction. For example, when the thickness of the first insulating layer 511 in the vertical direction is 250 μm, the reinforcing fibers 511b may be disposed within the first insulating layer 511 by being divided into three groups. For example, as shown in FIG. 9, when the thickness of the first insulating layer 511 in the vertical direction is 300 μm, the reinforcing fibers 511 b may be disposed within the first insulating layer 511 by being divided into four groups.

Accordingly, the first insulating layer 511 may be divided into a plurality of regions in the vertical direction. For example, the first insulating layer 511 may include a first region 511R1 that does not include reinforcing fibers 511b and a second region 511R2 that includes reinforcing fibers 511b, in the vertical direction.

The second region 511R2 of the first insulating layer 511 may be provided in multiple numbers, spaced apart from each other in the vertical direction, with the first region 511R1 of the first insulating layer 511 interposed between them.

Referring to FIGS. 4 to 6, when the reinforcing fibers 511b are divided into three groups, the second region 511R2 of the first insulating layer 511 may include at least three sub-regions spaced apart from each other with the first region 511R1 interposed between them.

For example, the first region 511R1 of the first insulating layer 511 may include first-first to first-fourth sub-regions 511R11, 511R12, 511R13, and 511R14 from a position adjacent to the upper surface 511U of the first insulating layer 511. In addition, the second region 511R2 of the first insulating layer 511 may include second-first to second-third sub-regions 511R21, 511R22, and 511R23 disposed between the first-first to first-fourth sub-regions 511R11, 511R12, 511R13, and 511R14, respectively. The second region 511R2 may be positioned further away from the upper surface 511U and the lower surface 511L of the first insulating layer 511 than the first region 511R1. This is because, when the reinforcing fibers 511b are exposed to the upper surface 511U or the lower surface 511L of the first insulating layer 511, physical reliability and electrical reliability of the circuit pattern layers may be deteriorated.

In the embodiment according to FIGS. 5 and 6, since the first through hole TH1 is formed using at least two coordinate codes by using the laser equipment, a concave portion and a convex portion are alternately provided at the inner wall of the first through hole TH1 along the vertical direction. In addition, a difference between a minimum width and a maximum width of the first through hole TH1 having the concave portion and the convex portion of the embodiment is smaller than a difference between a minimum width and a maximum width of the first through hole TH1 formed using one coordinate code by using the conventional laser equipment.

In addition, the concave portion may be provided in the first-first to first-fourth sub-regions 511R11, 511R12, 511R13, and 511R14, and the convex portion may be provided in the second-first to second-third sub-regions 511R21, 511R22; and 511R23. This is because an etching rate of a resin layer composed only of the resin 511a in the first insulating layer 511 is greater than an etching rate of a layer provided with the reinforcing fiber 511b, and therefore, the concave portion and the convex portion may be provided at the above-described positions, but are not limited thereto.

In the embodiment according to FIG. 5, an inner wall of the first through hole TH1 includes a first inner wall IW1 and a second inner wall IW2. The second inner wall IW2 of the first through hole TH1 may be provided as a convex portion that is convex toward an inner side of the first through hole TH1 compared to the first inner wall IW1.

That is, the inner wall of the first insulating layer 511 constituting the first through hole TH1 of the embodiment includes the second inner wall IW2 that is convex toward the first through hole TH1 based on the first inner wall IW1. In addition, referring to FIG. 5, the first inner wall IW1 may have an exemplary vertical slope, but is not limited thereto, and may be provided as a concave portion that is concave toward an outer surface of the first insulating layer 511.

At this time, the second inner wall IW2 of the embodiment may include a plurality of convex portions spaced apart from each other in the vertical direction. In addition, the convex portion can be a region where a state of increasing and decreasing width changes. For example, the convex portion may be provided as a curved surface having a constant curvature along the vertical direction, but is not limited thereto.

Through this, the embodiment can uniformly place the first through-electrode in the first through-hole TH1 by having the inner wall IW1 and IW2 of the first through-hole TH1 with a convex portion and a concave portion, thereby stably matching the impedance and reducing the voltage drop, current and/or signal loss. In addition, the reliability with respect to thermal stress can be improved. That is, the voltage drop or current and/or signal loss can be reduced by arranging a horizontal width of the first through electrode to be thicker than the thickness of the conventional vertical first through electrode 530 illustrated in FIG. 3a, and a structure can be more advantageous for heat dissipation.

The first inner wall IW1 can be formed in the first region 511R1 of the first insulating layer 511 among the first through holes TH1, and the second inner wall IW2 can be formed in the second region 511R2 of the first insulating layer 511 among the first through holes TH1.

That is, the embodiment forms the first through hole TH1 in the first insulating layer 511 having a thickness T1 of 250 μm or more using the laser equipment. At this time, when using the laser equipment, it may be difficult to easily remove the reinforcing fiber 511b provided in the first insulating layer 511. Therefore, the first insulating layer 511 of the embodiment may include a second inner wall IW2 that corresponds to the inner wall of the second region 511R2 of the first insulating layer 511 in which the reinforcing fibers 511b are disposed and is convex toward the first through hole TH1. In addition, the first inner wall IW1 and the second inner wall IW2 may each include a plurality of sub-parts.

For example, the first inner wall IW1 may include first-first to first-fourth sub-parts IW1-1, IW1-2, IW1-3, and IW1-4 based on those adjacent to the upper surface 511U of the first insulating layer 511. The second inner wall IW2 may include second-first to second-third sub-parts IW2-1, IW2-2, and IW2-3 respectively disposed between the first-first to first-fourth sub-parts IW1-1, IW1-2, IW1-3, and IW1-4.

A number of sub-parts of the second inner wall IW2 may correspond to a number of groups of reinforcing fibers 511b provided in the first insulating layer 511 Accordingly, the number of sub-parts of the second inner wall IW2 may be more than 2, 3 or more, 4 or more, or 5 or more.

The first through hole TH1 has a first width W1 in the horizontal direction in a region corresponding to the first-first sub-part IW1-1 of the first inner wall IW1 and then has a second width W2 smaller than the first width W1 in a region corresponding to the second-first sub-part IW2-1 of the second inner wall IW2. In addition, the first through hole TH1 has a first width W1 again in a region corresponding to the first-second sub-part IW1-2 of the first inner wall IW1 and then has a second width W2 smaller than the first width W1 in a region corresponding to the second-second sub-part IW2-2 of the second inner wall IW2. In addition, the first through hole TH1 has a first width W1 again in a region corresponding to the first-third sub-part IW1-3 of the first inner wall IW1 and then has a second width W2 smaller than the first width W1 in a region corresponding to the second-third sub-part IW2-3 of the second inner wall IW2. In addition, the first insulating layer 511 has a first width W1 again in a region corresponding to the first-fourth sub-part IW1-4 of the first inner wall IW1. However, referring to FIG. 9, the first through hole TH1 may not have a same first width W1 in each region corresponding to the first-first to the first-fourth sub-parts IW1-1, IW1-2, IW1-3, and IW1-4 of the first inner wall IW1, and may not have a same second width W2 in the second-first to the second-third sub-parts IW2-1, IW2-2, and IW2-3 of the second inner wall IW2.

The first insulating layer 511 of the embodiment includes reinforcing fibers 511b vertically spaced in groups of more than two, three or more, four or more, or five or more. In addition, the inner wall of the first insulating layer 511 in which the first through hole TH1 is formed includes a plurality of convex portions that are convex toward a center of the first through hole TH1 in a region in which the reinforcing fibers 511b are disposed. The plurality of convex portions may be spaced apart from each other in the vertical direction in the first insulating layer 511. In addition, each of the convex portions may extend from the inner wall of the first through hole TH1 along a circumferential direction of the inner wall of the first through hole TH1. At this time, the first width W1 of the first through hole TH1 may mean a width in a horizontal direction of a region having a maximum width in the entire region in the vertical direction. The second width W2 of the first through hole TH1 may mean a width in a horizontal direction of a region having a minimum width in the entire region in the vertical direction.

In a case of a through hole formed in an insulating layer of 250 μm or more using the laser equipment of the comparative example, the second width is less than 50% of the first width.

In contrast, the second width W2 of the embodiment can satisfy a range of 55% to 95% of the first width W1.

If the second width W2 is less than 55% of the first width W1, a width difference of the through hole becomes large, and thus plating characteristics in a plating process filling the through hole may deteriorate. For example, if the width difference is large, a difference in a plating growth rate in the plating process also becomes large, and accordingly, a void region of an empty space not filled with a metal material may exist inside the through hole. In addition, even if the second width W2 exceeds 95% of the first width W1, the plating characteristics in the plating process may deteriorate because a plating bridge does not exist.

Meanwhile, the first through electrode 530 and the insulating member 540 of the embodiment may be disposed in the first through hole TH1.

The first through electrode 530 may be in contact with the inner wall IW1 and IW2 of the first insulating layer 511 including the first through hole TH1. The insulating member 540 may be disposed at an inner side of the first through electrode 530 within the first through hole TH1. For example, the first through electrode 530 may be provided to surround an outer side of the insulating member 540 within the first through hole TH1.

The first through electrode 530 may have a predetermined thickness and be disposed on the inner wall of the first insulating layer 511 including the first through hole TH1. The thickness of the first through electrode 530 may mean a distance in a horizontal direction of the first through electrode 530. Specifically, the thickness of the first through electrode 530 may mean a width of the first through electrode 530 in the horizontal direction.

At this time, the first through electrode 530 may be divided into a plurality of parts. For example, the first through electrode 530 may include a concave portion disposed on the first inner wall IW1 corresponding to the first region 511R1 of the first insulating layer 511. In addition, the first through electrode 530 may include a convex portion disposed on the second inner wall IW2 corresponding to the second region 511R2 of the first insulating layer 511. In addition, a side surface of the first through electrode 530 having the concave portion and the convex portion may have a step in the vertical direction. Specifically, the concave portion of the first through electrode 530 does not overlap the reinforcing fiber 511b in the horizontal direction. In addition, the convex portion of the first through electrode 530 overlaps with the reinforcing fiber 511b in the horizontal direction. Preferably, the convex portion of the first through electrode 530 corresponds to the convex portion provided in the second inner wall IW2 of the first insulating layer 511. In addition, the concave portion of the first through electrode 530 corresponds to the concave portion provided in the first inner wall IW1 of the first insulating layer 511. In addition, referring to FIG. 9, the first through electrode 530 may have a shape in which the concave portion and the convex portion are alternately disposed along the vertical direction. At this time, the concave portion of the first through electrode 530 corresponds to the concave portion provided in the first inner wall IW1 of the first through hole TH1, and the convex portion of the first through electrode 530 corresponds to the convex portion provided in the second inner wall IW2 of the first through hole TH1, but is not limited thereto.

The first through electrode 530 may have a third thickness W3 in the horizontal direction in a region where the concave portion is provided. In addition, the first through electrode 530 may have a fourth thickness W4 in the horizontal direction in a region where the convex portion is provided. At this time, the third thickness W3 may correspond to the fourth thickness W4. For example, the third thickness W3 and the fourth thickness W4 may be identical to each other. That is, the first through electrode 530 may have a same thickness in the horizontal direction in each of a region having the concave portion and a region having the convex portion. Here, having the same thickness may mean that a difference in the thickness in the horizontal direction in the region having the concave portion and the region having the convex portion is 3 μm or less.

The thickness W3 and W4 of the first through electrode 530 in the horizontal direction may have a range of 10 μm to 25 μm If the thickness of the first through electrode 530 in the horizontal direction is less than 10 μm, the resistance of the first through electrode 530 may increase and the allowable current of the transmittable signal may decrease. In addition, if the thickness of the first through electrode 530 in the horizontal direction is less than 10 μm, the electrical characteristics may deteriorate. For example, if the thickness of the first through electrode 530 in the horizontal direction is less than 10 μm, the reinforcing fiber 511b exposed through the first through hole TH1 may not be stably covered by the first through electrode 530. In addition, if the reinforcing fiber 511b is not covered by the first through electrode 530, a problem of deterioration of electrical characteristics due to the reinforcing fiber 511b may occur. If the thickness of the first through electrode 530 in the horizontal direction exceeds 25 μm, a thickness deviation between the region having the concave portion of the first through electrode 530 and the region having the convex portion of the first through electrode 530 may increase due to the difference in plating speed growth in the process of forming the first through electrode 530.

The insulating member 540 may include a region whose width changes from the upper surface to the lower surface. For example, the insulating member 540 may have a plurality of concave portions that are concave toward an inner side direction and a plurality of convex portions that are convex toward the first through electrode 530. The concave portions of the insulating member 540 may be provided in a plurality of positions spaced apart in the vertical direction. In addition, each of the convex portions of the insulating member 540 may be provided between the plurality of concave portions of the insulating member 540.

According to the embodiment of FIG. 6, the insulating member 540 may include a first portion 541 having a fifth width W5 and a second portion 542 having a sixth width W6 smaller than the fifth width W5. In addition, a convex portion that is convex toward the first through electrode 530 may be provided at a side surface of the first portion 541 of the insulating member 540. In addition, a side surface of the second portion 542 of the insulating member 540 may be provided with a concave portion that is concave inwardly.

That is the inner wall of the first through hole TH1 of the first insulating layer 511 includes a convex portion corresponding to the reinforcing fiber 511b. Accordingly, the insulating member 540 may also be provided with a concave portion corresponding to the convex portion of the first through hole TH1. For example, the insulating member 540 may be provided with a concave portion that overlaps horizontally with the convex portion provided in the first through hole TH1. In addition, the insulating member 540 may be provided with a convex portion that overlaps horizontally with the concave portion provided in the first through hole TH1. At this time, in FIG. 6, the side surface of the first portion 541 of the insulating member 540 is illustrated as being vertical, but is not limited thereto. For example, the side surface of the first portion 541 may be provided as a convex portion having a convex curved surface toward the first through electrode 530.

The first portion 541 of the insulating member 540 may be provided in multiple numbers, spaced apart from each other in the vertical direction.

For example, as shown in FIG. 6, the first portion 541 of the insulating member 540 may include a first-first portion 541-1, a first-second portion 541-2, a first-third portion 541-3, and a first-fourth portion 541-4.

In addition, the second portion 542 of the insulating member 540 may include a second-first portion 542-1, a second-second portion 542-2, and a second-third portion 542-3. The second-first portion 542-1, the second-second portion 542-2, and the second-third portion 542-3 may be parts that overlap the reinforcing fiber 511b in the horizontal direction.

In addition, the first-first portion 541-1, the first-second portion 541-2, the first-third portion 541-3, and the first-fourth portion 541-4 may be parts that do not overlap with the reinforcing fiber 511b in the horizontal direction.

In addition, the second-first portion 542-1, the second-second portion 542-2, and the second-third portion 542-3 may have a width smaller than that of the first-first portion 541-1, the first-second portion 541-2, the first-third portion 541-3, and the first-fourth portion 541-4 due to the reinforcing fiber 511b.

Meanwhile, the first through electrode 530 may be composed of a plurality of layers. For example, the first through electrode 530 may be formed together with the first circuit pattern layer 521 and the second circuit pattern layer 522 when the first circuit pattern layer 521 and the second circuit pattern layer 522 are formed. Accordingly, the first through electrode 530 may have a layer structure corresponding to the layers constituting the first circuit pattern layer 521 and the second circuit pattern layer 522.

The first circuit pattern layer 521 may include a plurality of metal layers.

For example, the first circuit pattern layer 521 may include a first metal layer 521-1 disposed on the first insulating layer 511, a second metal layer 521-2 disposed on the first metal layer 521-1, and a third metal layer 521-3 disposed on the second metal layer 521-2.

The first metal layer 521-1 of the first circuit pattern layer 521 may refer to a copper layer attached to a surface of the first insulating layer 511.

The second metal layer 521-2 of the first circuit pattern layer 521 may be a plating layer formed on the first metal layer 521-1 through electroless plating. For example, the second metal layer 521-2 of the first circuit pattern layer 521 may be a chemical copper plating layer.

The third metal layer 521-3 of the first circuit pattern layer 521 may be a plating layer formed through electrolytic plating of the second metal layer 521-2 as a seed layer. For example, the third metal layer 521-3 of the first circuit pattern layer 521 may be an electrolytic plating layer.

At this time, as illustrated in FIG. 7, the third metal layer 521-3 of the first circuit pattern layer 521 in the first embodiment may be disposed on an upper surface of the insulating member 540. In this case, the third metal layer 521-3 of the first circuit pattern layer 521 may be formed by performing multiple electrolytic plating process.

In addition, as illustrated in FIG. 8, the third metal layer 521-3 of the first circuit pattern layer 521 in the second embodiment may not cover the upper surface of the insulating member 540. In this case, the third metal layer 521-3 of the first circuit pattern layer 521 may be formed by performing one electrolytic plating process. At this time, the third metal layer 521-3 of the first circuit pattern layer 521 may not overlap the upper surface of the insulating member 540 in the vertical direction.

Meanwhile, the first through electrode 530 may include a fourth metal layer 530-1 corresponding to the second metal layer 521-2 of the first circuit pattern layer 521 and a fifth metal layer 530-2 corresponding to the third metal layer 521-3 of the first circuit pattern layer 521 and disposed on the fourth metal layer 530-1.

In addition, the fourth metal layer 530-1 of the first through electrode 530 may be provided on the inner wall of the first insulating layer 511 including the first through hole TH1. In addition, the fifth metal layer 530-2 of the first through electrode 530 may be disposed between the fourth metal layer 530-1 of the first through electrode 530 and the insulating member 540.

Meanwhile, the thickness W4 and W5 of the first through electrode 530 in the horizontal direction may mean a sum of thicknesses of the fourth metal layer 530-1 and the fifth metal layer 530-2 of the first through electrode 530 in the horizontal direction.

Meanwhile, referring to FIG. 9, according to an embodiment, a thickness of the first insulating layer 511 in the vertical direction may be 400 μm or more, and accordingly, the reinforcing fibers 511b may be disposed to be divided into four groups in the vertical direction. Accordingly, the inner wall of the first through hole TH1 of the first insulating layer 511 may be provided with protruding portions corresponding to the four groups of reinforcing fibers 511b, respectively.

Referring to FIG. 9, the first through electrode 530 disposed on the side wall of the first through hole TH1 includes one side surface facing the insulating member 540 and other side surface facing the first insulating layer 511, and the one side surface includes a convex portion protruding toward the insulating member 540 and a concave portion concave toward the first through hole TH1. The first through electrode 530 illustrated in FIG. 9 illustrates one cross-section, and the one side surface of the first through electrode 530 is structured to surround the insulating member 540.

The concave portions of the first through electrode 530 may face each other and overlap along the horizontal direction, and the convex portions of the first through electrode 530 may face each other and overlap along the horizontal direction. In addition, the convex portion and the concave portion may have a structure in which they are alternately disposed along the vertical direction. Through this, the thickness of the first through electrode 530 can be disposed relatively uniformly in the horizontal direction, and can be disposed thicker compared to a process using a drill machine.

The other side surface of the first through electrode 530 can have a different shape from the one side surface. That is, the other side surface that overlaps along the horizontal direction with the one side surface where the concave portion of the first through electrode 530 is disposed may not have a concave surface or may have different curvatures. Referring to FIG. 9, a curvature of one side surface of the first through electrode 530 and a curvature of other side surface that is horizontally overlapped with the one side surface having the concave portion are different from each other. Through this, a bonding strength between the insulating member 540 and the first through electrode 530 can be improved, heat dissipation characteristics can be improved, and mechanical reliability of the semiconductor package substrate can be improved by controlling the stress. Similarly, the convex portion provided at one side surface of the first through electrode 530 may have a different curvature from the convex portion of the other side surface that overlaps the convex portion of the one side surface in the horizontal direction. The convex portion provided at the other side surface is arranged in a structure that surrounds glass fibers, unlike the convex portion provided at the one side surface, and therefore the curvature of the convex portion provided at the other side surface may be different from the curvature of the convex portion provided at the one side surface. Specifically, when the first through electrode 530 surrounds glass fibers, a thickness of the first through electrode 530 in the horizontal direction must be 10 μm or more to prevent a problem of deterioration of electrical characteristics. Therefore, in order to prevent deterioration of electrical characteristics while the convex portion provided at the other side surface surrounds glass fibers, the convex portion of the one side surface and the convex portion of the other side surface may be arranged to have different curvatures.

FIGS. 10 to 14 are drawings showing a part of a method for manufacturing a semiconductor package substrate according to an embodiment in the order of processes. Hereinafter, a process for forming a first through hole TH1 in a first insulating layer 511 is described.

Referring to FIG. 10, the embodiment prepares a first insulating layer 511. The first insulating layer 511 may be CCL. Therefore, a copper layer may be disposed on each of both sides of the first insulating layer 511. The copper layer may include a first metal layer 521-1 of a first circuit pattern layer 521 and a first metal layer 522-1 of a second circuit pattern layer 522.

Thereafter, the embodiment may perform a process for forming a first through hole TH1 in the first insulating layer 511.

The first through hole TH1 may be formed by a plurality of laser processes using a plurality of coordinate codes.

At this time, the first insulating layer 511 has a thickness in a vertical direction of 250 μm or more. Therefore, it may be difficult to form the first through hole TH1 passing through the first insulating layer 511 only on one side of the first insulating layer 511. Therefore, the embodiment may proceed with a process of primarily forming a part of the first through hole TH1 on an upper side of the first insulating layer 511.

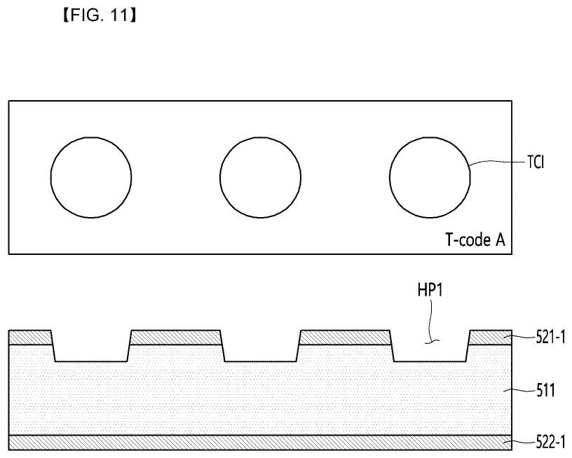

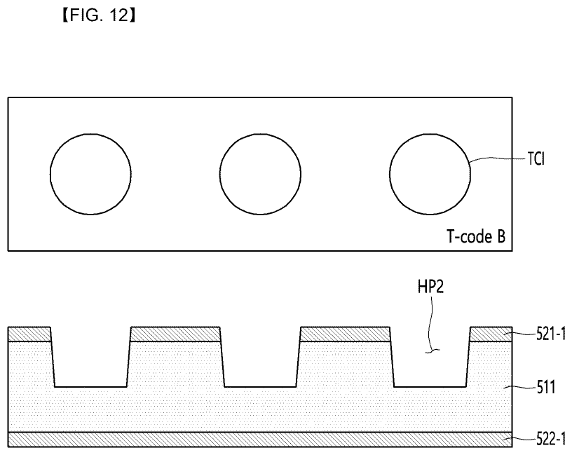

To this end, referring to FIG. 11, the embodiment may proceed with a process of forming a part of the first through hole TH1 at the upper side of the first insulating layer 511 using the first coordinate code (T-code A). The first coordinate code (T-code A) may include location information (TCI) corresponding to a location where the first through hole TH1 is to be formed. In addition, the embodiment can form a part of the first through hole TH1 by irradiating a laser from the upper side of the first insulating layer 511 using the first coordinate code (T-code A). At this time, in the process of forming a part of the first through hole TH1 using the first coordinate code (T-code A), a first mask having an opening of the first size can be used. In addition, the embodiment can perform a process of forming a first portion HP1, which is a part of the first through hole TH1, on the upper side of the first insulating layer 511 by irradiating a laser with a first laser energy intensity through the opening of the first mask.

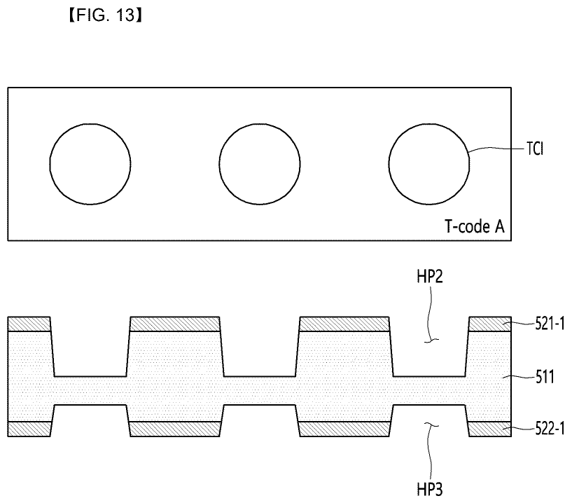

Thereafter, referring to FIG. 12, the embodiment can perform a process of forming a second portion HP2 connected to the first portion BP1 on the upper side of the first insulating layer 511 using the second coordinate code (T-code B). At this time, the second coordinate code (T-code B) may include location information (TCI) corresponding to the first coordinate code (T-code A).

In addition, in the embodiment, when the second coordinate code (T-code B) is used, conditions different from the laser process conditions used when the first coordinate code (T-code A) is used are applied to form a second portion HP2 of the first through hole TH1 connected to the first portion BP1 of the first through hole TH1.

At this time, in the process of forming the first portion BP1 of the first through hole TH1 using the second coordinate code (T-code B), a second mask having an opening of a second size smaller than the first size may be used. In addition, in the embodiment, the second portion HP2 of the first through hole TH1 may be formed on the upper side of the first insulating layer 511 by irradiating a laser of a second energy intensity greater than the first energy intensity through the opening of the second mask.

Accordingly, the embodiment may allow widths of the first portion HP1 and the second portion HP2 of the first through hole TH1 in the horizontal direction to be substantially the same. However, the first insulating layer 511 includes reinforcing fibers 511b. Therefore, in the first portion HP1 and the second portion HP2 of the first through hole TH1, a protrusion may be provided in a region that overlaps the reinforcing fibers 511b in the horizontal direction.

In addition, referring to FIG. 13, the embodiment may perform a process of forming a remaining part of the first through hole TH1 on a lower side of the first insulating layer 511 using the first coordinate code (T-code A). Specifically, the embodiment can form a third portion HP3 of the first through hole TH1 that is aligned vertically with the first portion HP1 and the second portion HP2 of the first through hole TH1 by applying the first laser process condition according to the first coordinate code (T-code A).

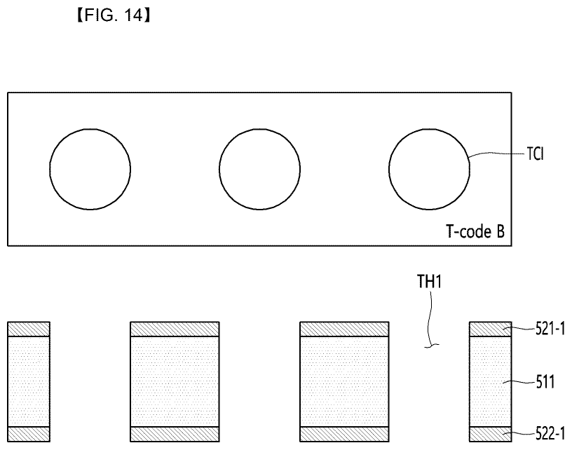

Next, referring to FIG. 14, the embodiment can perform a process of forming a fourth portion HP4 connected to the third portion HP3 of the first through hole TH1 by using the second coordinate code (T-code B). The fourth portion HP4 is connected to the second portion HP2, and thus a final first through hole TH1 can be formed.

On the other hand, when the semiconductor package substrate having the above-described characteristics of the invention is used in an IT device or home appliance such as a smart phone, a server computer, a TV, and the like, functions such as signal transmission or power supply can be stably performed. For example, when a semiconductor package substrate having the features of the present invention performs a semiconductor package function, the circuit board can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the semiconductor package substrate having the above-described characteristics of the invention can maintain the stable function of the IT device or home appliance, so that the entire product and the semiconductor package substrate to which the present invention is applied can achieve functional unity or technical interlocking with each other.

When the semiconductor package substrate having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the semiconductor package substrate to which the present invention is applied can achieve functional integrity or technical interlocking with each other. Furthermore, when the semiconductor package substrate having the characteristics of the invention described above is used in a transportation device such as a vehicle, a high-current signal required by the vehicle can be transmitted at high speed, thereby improving the safety of the transportation device. Furthermore, the semiconductor package substrate and the semiconductor package including the semiconductor package can be operated normally even in unexpected situations occurring in various driving environments of the transportation device, thereby safely protecting the driver.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A circuit board comprising:
an insulating layer having an upper surface and a lower surface and including a reinforcing member; and
a through electrode passing through the upper surface and the lower surface of the insulating layer,
wherein the insulating layer is provided with a first region having the reinforcing member and a second region not having the reinforcing member alternately along a vertical direction, and
wherein a side surface of the through electrode includes a concave portion overlapping the first region along a horizontal direction and a convex portion overlapping the second region along the horizontal direction.

2. The circuit board of claim 1, wherein the reinforcing member is arranged to extend along the horizontal direction within the first region of the insulating layer,
wherein the insulating layer includes a through hole passing through the upper surface and the lower surface of the insulating layer, and
wherein a side wall of the through hole includes a convex portion overlapping the first region and the concave portion of the through electrode along the horizontal direction, and a concave portion overlapping the second region and the convex portion of the through-electrode along the horizontal direction.

3. The circuit board of claim 2, wherein the concave portion and the convex portion of each of the through electrodes and the through holes are alternately provided along the vertical direction.

4. The circuit board of claim 1, further comprising:
an insulating member passing through the upper surface and the lower surface of the insulating layer, and
wherein the through electrode is provided to surround an outer side of the insulating member.

5. The circuit board of claim 1, wherein the concave portion and the convex portion of the through electrode are different slopes or curvatures.

6. The circuit board of claim 4, wherein the insulating member includes a first portion having a first width in a horizontal direction, and a second portion having a second width greater than the first width in the horizontal direction.

7. The circuit board of claim 6,
wherein the first portion of the insulating member overlaps the concave portion of the through electrode and the first region in the horizontal direction, and
wherein the second portion of the insulating member overlaps the convex portion of the through electrode and the second region in the horizontal direction.

8. The circuit board of claim 1, wherein the horizontal direction includes a first horizontal direction and a second horizontal direction perpendicular to the first horizontal direction, and
wherein the reinforcing member arranged in the first region of the insulating layer includes:
a first fiber disposed in the first horizontal direction and a second fiber disposed in the second horizontal direction.

9. The circuit board of claim 1, wherein the first region of the insulating layer is located farther from the upper surface of the insulating layer than the second region of the insulating layer.

10. The circuit board of claim 8, wherein the first region of the insulating layer is located farther from the lower surface of the insulating layer than the second region of the insulating layer.

11. The circuit board of claim 1, wherein a first length of the convex portion in the vertical direction is different from a second length of the concave portion in the vertical direction.

12. The circuit board of claim 11, wherein the first length is smaller than the second length.

13. The circuit board of claim 11, wherein the first length and the second length each have a range of 10 μm to 25 μm.

14. The circuit board of claim 1, wherein the through electrode includes a first portion including the concave portion, and a second portion including the convex portion, and
wherein a thickness of the first portion in the horizontal direction is same as a thickness of the second portion in the horizontal direction.

15. The circuit board of claim 1, wherein the through electrode includes a first metal layer disposed on an inner wall of a through hole passing through the insulating layer, and a second metal layer disposed on the first metal layer.

16. The circuit board of claim 4, wherein the through electrode includes a first side surface in contact with an inner wall of a through hole passing through the insulating layer, and a second side surface in contact with the insulating member,
wherein the convex portion and the concave portion of the through electrode are provided at the first side surface of the through electrode, and
wherein the second side surface of the through electrode includes a concave portion that overlaps the convex portion provided at the first side surface along the horizontal direction, and a convex portion that overlaps the concave portion provided at the first side surface along the horizontal direction.

17. The circuit board of claim 1, wherein the insulating layer is a core insulating layer,
wherein an upper build-up structure is disposed on an upper surface of the core insulating layer, and
wherein a lower build-up structure is disposed on a lower surface of the core insulating layer.

18. The circuit board of claim 17, further comprising:
a connection member embedded in the upper build-up structure.

19. The circuit board of claim 18, further comprising:
a semiconductor device disposed on the upper build-up structure.

20. The circuit board of claim 19, wherein the semiconductor device includes a first semiconductor device and a second semiconductor device spaced apart along the horizontal direction, and wherein each of the first semiconductor device and the second semiconductor device includes a region overlapping the connection member along the vertical direction.
